(19) United States
(12) Patent Application Publication
(10) Pub. No.: US 2024/0146273 A1
(43) Pub. Date: May 2, 2024

(54) MEDIA PRESENTATION DEVICE OR MICROPHONE CALIBRATION VIA EVENT DETECTION

(71) Applicant: Caavo Inc, Milpitas, CA (US)

(72) Inventors: Ashish D. Aggarwal, Stevenson Ranch, CA (US); Vinod K. Gopinath, Bangalore (IN); Neha Mittal, Bangalore (IN); Siddharth Kumar, Bangalore (IN); Sharath H. Satheesh, Bangalore (IN)

(21) Appl. No.: 18/493,143

(22) Filed: Oct. 24, 2023

(30) Foreign Application Priority Data
Oct. 27, 2022 (IN) 202241061237

(51) Int. Cl. H03G 3/32; G06F 3/16

(52) U.S. Cl. CPC H03G 3/32; G06F 3/165

(57) ABSTRACT

Systems, methods, and computer readable storage medium are described for media presentation device or microphone calibration via event detection. An adjustment event is detected based on an analysis of a received signal. A determination to adjust at least one of a volume setting of a media presentation device or a gain setting of a microphone is made based at least on the detected adjustment event. Responsive to the determination, a first command is transmitted to at least one of the media presentation device or the microphone. In an aspect, the received signal is an audio data signal received from a listening device. In another aspect, the received signal is a command signal received from a second computing device via a network interface, the command signal comprising instructions to adjust the volume setting of the media presentation device, the second computing device remotely located and associated with a second user.

### CROSS-REFERENCE TO RELATED APPLICATIONS

This application claims priority to India Provisional Application No. 202241061237, filed on Oct. 27, 2022, entitled “SPEAKER OR MICROPHONE CALIBRATION VIA AUDIO SIGNAL CAPTURE,” which is incorporated by reference herein in its entirety.

### BACKGROUND

Devices in a living room may include speakers for outputting audio. Such speakers may be controlled by a remote control device (“remote”). As such, the user needs to have the remote control device in hand or within reach to adjust the volume settings of the speakers.

### BRIEF SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Methods, systems, and apparatuses are described for media presentation device and/or microphone calibration via event detection. In one aspect, a system comprises an event detector and a device setting adjustment component. The event detector detects an adjustment event based on an analysis of a received signal. The device setting adjustment component determines to adjust at least one of a volume setting of a media presentation device or a gain setting of a microphone based at least on the detected adjustment event. Responsive to the determination, the device setting adjustment component transmits a first command to at least one of the media presentation device or the microphone. In further aspect, the received signal is an audio data signal received from a listening device. In an alternative further aspect, the received signal is a command signal received from a second computing device via a network interface, the command signal comprising instructions to adjust the volume setting of the media presentation device, the second computing device remotely located and associated with a second user.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1 is a block diagram of a system configured to calibrate a media presentation device or a microphone, according to an exemplary embodiment.

FIG. 2 is a block diagram of a media system configured to calibrate a media presentation device or a microphone via event detection, according to an exemplary embodiment.

FIG. 3 is a block diagram of a media system configured to calibrate a media presentation device or a microphone via event detection, according to another exemplary embodiment.

FIG. 4A is a flowchart of a process for media presentation device or microphone calibration via event detection, according to an exemplary embodiment.

FIG. 4B is a flowchart of a process for detecting an adjustment event based on an analysis of a command signal, according to an example embodiment.

FIG. 4C is a flowchart of a process for detecting an adjustment event based on an analysis of an audio data signal, according to an example embodiment.

FIG. 5A is a flowchart of a process for media presentation device calibration via event detection, according to an exemplary embodiment.

FIG. 5B is a flowchart of a process for determining to adjust a volume setting or a gain setting, according to an exemplary embodiment.

FIG. 6 is a flowchart of a process for transmitting a command to further adjust a volume setting or a gain setting, according to an exemplary embodiment.

FIG. 7 is a block diagram of a system for determining presence of a user, according to an exemplary embodiment.

FIG. 8A is a flowchart of a process for determining presence of a user, according to an exemplary embodiment.

FIG. 8B is a flowchart of a process for turning on a microphone of a remote control device based on determining a user presence, according to an exemplary embodiment.

FIG. 9 is a flowchart of a process for detecting a triggering event, according to an exemplary embodiment.

FIG. 10 is a block diagram of a media system configured to calibrate a media presentation device or a microphone via event detection, according to another exemplary embodiment.

FIG. 11 is a block diagram of a media system configured to calibrate a speaker or a microphone via event detection, according to another exemplary embodiment.

FIG. 12 is a block diagram of a computer system, according to an exemplary embodiment.

Embodiments will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### I. Introduction

The present specification discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

Numerous exemplary embodiments are described herein. Any section/subsection headings provided herein are not intended to be limiting. Embodiments are described throughout this document, and each embodiment may be eligible for inclusion within multiple different sections or subsections. Furthermore, it is contemplated that the disclosed embodiments may be combined with each other in any manner. That is, the embodiments described herein are not mutually exclusive of each other and may be practiced and/or implemented alone, or in any combination.

A method is described herein. The method includes: detecting an adjustment event based on an analysis of at least one of: an audio data signal received from a listening device, or a command signal received from a second computing device via a network interface, the command signal comprising instructions to adjust a volume setting of a media presentation device, the second computing device associated with a second user and remotely located from the first computing device; determining to adjust at least one of the volume setting of the media presentation device or a gain setting of a microphone based at least on the detected adjustment event; and responsive to said determining, transmitting a first command to at least one of the media presentation device or the microphone.

In an implementation of the method, said detecting the adjustment event is based on the analysis of the audio data signal; the listening device comprises the microphone; and the audio data signal is representative of audio played back by the media presentation device and captured by the microphone.

In an implementation of the method, the second computing device comprises the microphone.

In an implementation of the method, said determining to adjust at least one of the volume setting or the gain setting comprises: determining the volume setting of the media presentation device is at a maximum level, and determining to increase the gain of the microphone; and said transmitting the first command to the microphone comprises transmitting the first command to the second computing device to cause the second computing device to increase the gain of the microphone.

In an implementation of the method, said detecting the adjustment event comprises determining a volume of the audio data signal.

In an implementation of the method, said determining to adjust at least one of the volume setting or the gain setting comprises: determining to increase the volume setting if the volume of the audio data signal is below a first threshold; and determining to decrease the volume setting if the volume of the audio data signal is above a second threshold greater than the first threshold.

In an implementation of the method, the method further comprises, subsequent to said transmitting the first command: determining audio representative of user interaction has not been detected for a predetermined time; and transmitting a second command to increase the volume setting of the media presentation device or increase the gain setting of the microphone device.

In an implementation of the method, the method further comprises determining a user is proximate to the listening device based on one or more of: an analysis of an image or a video of the user captured by a camera, an analysis of an output of a sensor of the listening device, an analysis of data obtained from a smart home application associated with the user, or an analysis of an output of a motion detector. Said analyzing the received audio data signal is performed responsive to determining the user is proximate to the listening device.

In an implementation of the method, the method further comprises transmitting a second command to the remote control device responsive to determining the user is proximate to the remote control device, the second command comprising instructions to enable processing of audio captured by the microphone.

In an implementation of the method, the first command comprises one or more of: instructions to increase the volume setting of the media presentation device; instructions to decrease the volume setting of the media presentation device; instructions to increase the gain setting of the microphone; or instructions to decrease the gain setting of the microphone.

In an implementation of the method, the method further comprises detecting a triggering event. Said analyzing the received audio data signal is performed responsive to detecting the triggering event.

In an implementation of the method, the triggering event comprises at least one of: detecting an incoming audio or video call; detecting an indication that an audio input feature of an application has been enabled; determining that an application is in a state to accept user input; or detecting that an application with audio input features has been launched.

A system is described herein. The system comprises an event detector and a device setting adjustment component. The event detector detects an adjustment event based on an analysis of at least one of: an audio data signal received from a listening device, or a command signal received from a computing device via a network interface of the system, the command signal comprising instructions to adjust a volume setting of a media presentation device, the computing device associated with a second user and remotely located from the system. The device setting adjustment component: determines to adjust a gain setting of a microphone based at least on the detected adjustment event; and responsive to the determination to adjust the gain setting, transmits a first command to the microphone, the first command comprising instructions to adjust the gain setting.

In an implementation of the system, the event detector detects the adjustment event based on the analysis of the audio data signal; the listening device comprises the microphone; and the audio data signal is representative of audio played back by the media presentation device and captured by the microphone.

In an implementation of the system, the computing device comprises the microphone.

In an implementation of the system, to determine to adjust the gain setting, the device setting adjustment component: determines the volume setting of the media presentation device is at a maximum level, and determines to increase the gain of the microphone; and to transmit the first command to the microphone, the device setting adjustment component transmits the first command to the computing device to cause the computing device to increase the gain of the microphone.

In an implementation of the system, to detect the adjustment event, the event detector determines a volume of the audio data signal.

In an implementation of the system, to determine to adjust the gain setting the device setting adjustment component further: determines to increase the gain setting if the volume of the audio data signal is below a first threshold; and determines to decrease the gain setting if the volume of the audio data signal is above a second threshold greater than the first threshold.

In an implementation of the system, subsequent to the transmission of the first command to the microphone, the event detector determines audio representative of user interaction has not been detected for a predetermined time; and the device setting adjustment component further transmits a second command comprising instructions to increase the gain setting of the microphone device.

In an implementation of the system, the system further comprises a user presence determiner that determines a user is proximate to the listening device. The audio analyzer analyzes the received audio data signal responsive to the user presence determiner having determined that the user is proximate to the listening device.

In an implementation of the system, the user presence determiner determines the user is proximate to the listening device based at least on an analysis of an image of the user captured by a camera.

In an implementation of the system, the user presence determiner determines the user is proximate to the listening device based at least on an analysis of a video of the user captured by a camera.

In an implementation of the system, the user presence determiner determines the user is proximate to the listening device based at least on an analysis of an output of a sensor of the listening device.

In an implementation of the system, the user presence determiner determines the user is proximate to the listening device based at least on an analysis of data obtained from a smart home application associated with the user.

In an implementation of the system, the user presence determiner determines the user is proximate to the listening device based at least on an analysis of an output of a motion detector.

In an implementation of the system, the system further comprises a microphone control component that, responsive to the user presence determiner having determined that the user is proximate to the listening device, transmits a second command to the listening device. The second command comprises instructions to enable processing of the microphone.

In an implementation of the system, the first command comprises instructions to increase the volume setting of the media presentation device.

In an implementation of the system, the first command comprises instructions to decrease the volume setting of the media presentation device.

In an implementation of the system, the first command comprises instructions to increase the gain setting of the microphone.

In an implementation of the system, the first command comprises instructions to decrease the gain setting of the microphone.

In an implementation of the system, the system further comprises a triggering event detector that detects a triggering event. The audio analyzer analyzes the received audio data signal responsive to the triggering event detector having detected the triggering event.

In an implementation of the system, the triggering event comprises at least detecting an incoming audio or video call.

In an implementation of the system, the triggering event comprises at least detecting an indication that an audio input feature of an application has been enabled.

In an implementation of the system, the triggering event comprises at least determining that an application is in a state to accept user input.

In an implementation of the system, the triggering event comprises at least detecting that an application with audio input features has been launched.

Another system is described herein. The another system comprises an event detector and a device setting adjustment component. The event detector detects a first adjustment event based on an analysis of at least one of: an audio data signal received from a listening device, or a command signal received from a computing device via a network interface of the system, the command signal comprising instructions to adjust a volume setting of a media presentation device, the computing device associated with a second user and remotely located from the system. The device setting adjustment component determines to adjust a volume setting of the media presentation device based at least on the first adjustment event; and responsive to the determination to adjust the volume setting, transmits a first command to the media presentation device, the first command comprising instructions to adjust the volume setting.

In an implementation of the another system, the event detector detects the adjustment event based on the analysis of the audio data signal; the listening device comprises the microphone; and the audio data signal is representative of audio played back by the media presentation device and captured by the microphone.

In an implementation of the another system, the event detector detects a second adjustment event based on an analysis of audio captured by the listening device subsequent to the transmission of the first command; and the device setting adjustment component further: determines the volume setting of the media presentation device is at a maximum level, determines to increase a gain setting of a microphone of the computing device, and transmits a second command to the computing device to cause the computing device to increase the gain setting of the microphone.

In an implementation of the another system, to detect the adjustment event, the event detector determines a volume of the audio data signal.

In an implementation of the another system, to determine to adjust the volume setting, the device adjustment component further: determines to increase the volume setting if the volume of the received audio signal is below a first threshold; and determines to decrease the volume setting if the volume of the received audio signal is above a second threshold greater than the first threshold.

In an implementation of the another system, subsequent to the transmission of the first command to the microphone, the event detector determines audio representative of user interaction has not been detected for a predetermined time; and the device setting adjustment component further transmits a second command comprising instructions to increase the volume setting of the media presentation device.

In an implementation of the another system, the another system further comprises a user presence determiner that operates in a manner similar to the user presence determiner in any of the implementations of the foregoing system.

In an implementation of the another system, the another system further comprises a microphone control component that operates in a manner similar to the microphone control component in any of the implementations of the foregoing system.

In an implementation of the another system, the first command comprises instructions similar to those described in any of the implementations of the foregoing system.

In an implementation of the another system, the another system further comprises a triggering event detector that operates in a manner similar to the triggering event detector in any of the implementations of the foregoing system.

A computer-readable storage medium having program instructions recorded thereon is described herein. The program instructions, when executed by a processor circuit perform operations corresponding to any of the foregoing methods or functions of the foregoing system and/or the foregoing another system.

A switching device is described herein. The switching device comprises the foregoing system, comprises the foregoing another system, and/or is configured to perform any of the foregoing methods.

### II. Example Embodiments for Calibrating via Event Detection

Embodiments are provided for media presentation device and/or microphone calibration via event detection. For instance, a device (e.g., a switching device or other consumer electronic device) detects an adjustment event based on an analysis of one or more signals (e.g., an audio data signal, a command signal, or another signal in which the device detects an adjustment event) and determines whether or not to calibrate a media presentation device and/or a microphone. Examples of a media presentation device include, but are not limited to, a speaker, a consumer electronic device comprising a speaker, a consumer electronic device coupled to a speaker, or another consumer electronic device configured to present media. Depending on the implementation, the microphone may be a microphone of a listening device proximate to the media presentation device or a microphone of a computing device that communicates with the device over a network. Examples of a listening device include, but are not limited to, a smart home device, a remote control device, or another device in a system (e.g., a media system) that includes a microphone. In one aspect of the present disclosure, the device transmits a command to the media presentation device to adjust (i.e., increase or decrease) a volume setting of the media presentation device. In another aspect of the present disclosure, the device transmits a command to the microphone (or the listening device or computing device comprising the microphone) to adjust (i.e., increase or decrease) a gain setting (and/or a sensitivity setting) of the microphone.

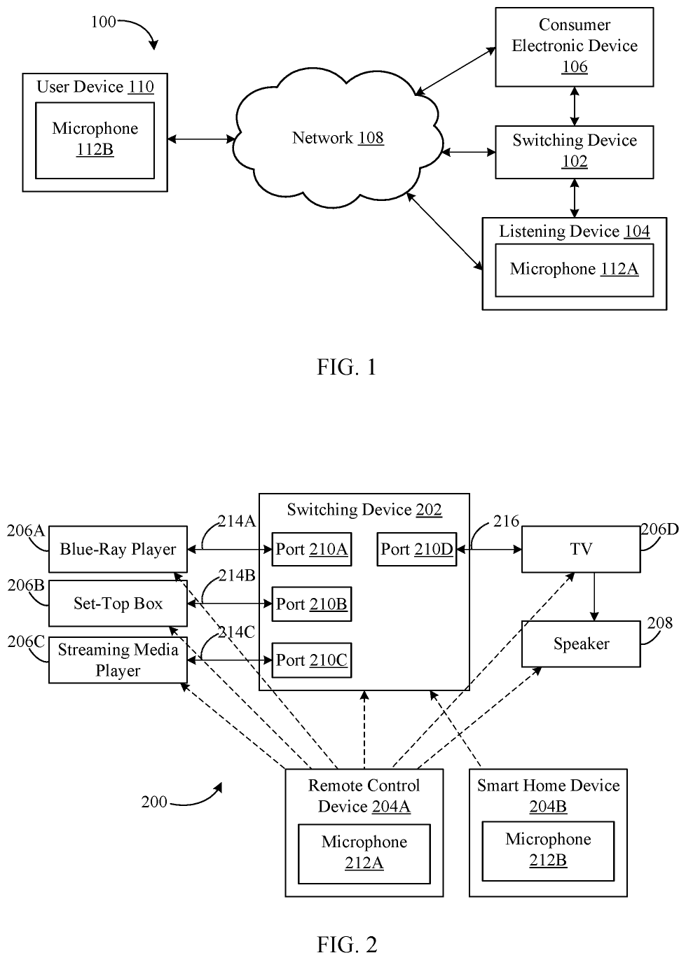

To help illustrate techniques for calibrating a media presentation device or a microphone based on event detection, FIG. 1 will now be described. FIG. 1 is a block diagram of a system configured to calibrate a media presentation device or a microphone, according to an exemplary embodiment. As shown in FIG. 1, system 100 includes a switching device 102, a listening device 104, a consumer electronic device 106, and a user device 110. As also shown in FIG. 1, listening device 104 comprises a microphone 112A and user device 110 comprises a microphone 112B. Each of switching device 102, listening device 104, consumer electronic device 106, and user device 110 are communicatively coupled via a network 108. Network 108 may comprise one or more networks such as local area networks (LANs), wide area networks (WANs), enterprise networks, the Internet, etc., and may include one or more of wired and/or wireless portions. The features of system 100 are described in detail as follows.

Switching device 102 is configured to select (e.g., switch between) different audio and/or video source devices that are coupled to ports of switching device 102 (not shown in FIG. 1 for brevity). In accordance with an embodiment, switching device 102 is an HDMI-Based switching device, but the embodiments described herein are not so limited.

Listening device 104 is configured to power, manage, control, and/or otherwise support microphone 112A. Examples of listening device 104 include, but are not limited to, a remote control device or a smart home device, as described elsewhere herein. In accordance with an embodiment, listening device 104 is operable to control any or all of switching device 102 and/or consumer electronic device 106. Listening device 104 may include a display screen and/or one or more physical interface elements (e.g., buttons, sliders, jog shuttles, etc.). In accordance with an embodiment, the display screen (or a portion thereof) may be a capacitive touch display screen. The display screen may be configured to display one or more virtual interface elements (e.g., icons, buttons, search boxes, etc.). The display screen may be configured to enable a user to interact, view, search, and/or select content for viewing via any of switching device 102 and/or consumer electronic device 106.

Consumer electronic device 106 is a device configured to provide or receive media content signals for playback. For instance, in accordance with an embodiment, consumer electronic device 106 is configured to provide media content signals for playback and is referred to as a “source” device. In accordance with an alternative embodiment, consumer electronic device 106 is configured to receive media content signals and is referred to as a “sink” device. In accordance with another alternative embodiment, consumer electronic device 106 performs functions of both a source and sink device. Media content signals may include audio data signals, video data signals, or a combination of audio and video data signals. Examples of consumer electronic devices include, but are not limited to, televisions (TVs), HDTVs, projectors, speakers, DVD players, Blu-ray players, video game consoles, set-top boxes, streaming media players, etc. Examples of streaming devices include, but are not limited to, Roku™ devices, AppleTV™ devices, Chromecast™ devices, and/or the like.

In accordance with an embodiment, switching device 102, listening device 104, and/or consumer electronic device 106 are part of a media system. The media system may be associated with a user (e.g., an owner, a family user, a household user, an individual user, a service team user, a group of users, etc.). Further examples of media systems are described with respect to FIGS. 2, 3, 10, and 11, as well as elsewhere herein. As shown in FIG. 1, the media system comprises one switching device 102, one listening device 104, and one consumer electronic device 106. Alternatively, a media system may comprise any number of switching devices, listening devices, and consumer electronic devices. For instance, system 100 may comprise a smart home device, switching device 102, a TV, a streaming media player, a Blue-Ray player, and a respective remote control device operable to control each of switching device 102, the TV, the streaming media player, and the Blue-Ray player.

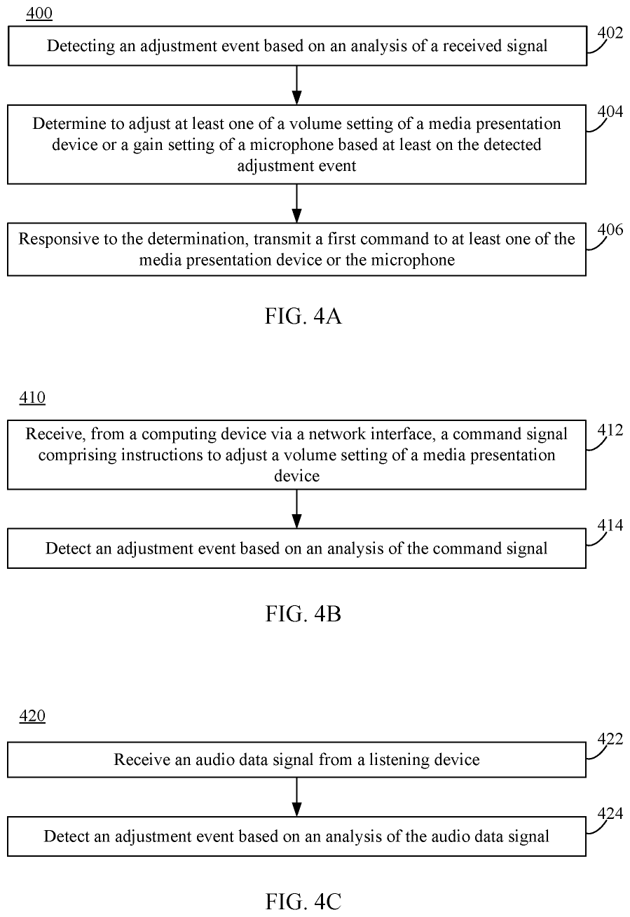

User device 110 is a computing device associated with a user. User device 110 may be any type of stationary or mobile processing device, as described elsewhere herein. In accordance with an embodiment, user device 110 is remotely located from the media system comprising switching device 102, listening device 104, and consumer electronic device 106 (e.g., in another building, in another city, in another state, in another country, and/or otherwise remotely located from the media system). For instance, user device 110 may be a consumer electronic device of another media system (e.g., a media system different from the media system comprising switching device 102, listening device 104, and consumer electronic device 106). In this context, user device 110 may be configured to operate in a manner similar to consumer electronic devices described elsewhere herein. In accordance with another embodiment, user device 110 is a switching device of such another media system and operates in a manner similar to switching device 102. In accordance with another embodiment, user device 110 is a listening device that operates in a manner similar to listening device 104. In accordance with an embodiment, a user of user device 110 interacts with an interface of user device 110 to initiate a call to a user of switching device 102, issue a command to switching device 102, and/or receive a call from a user of switching device 102. Additional details regarding issuing commands from a device remotely located from another device are described with respect to FIG. 4B, as well as elsewhere herein.

As noted above and shown in FIG. 1, listening device 104 and user device 110 each comprise a respective microphone 112A and microphone 112B. Microphone 112A and microphone 112B may be configured to capture audio signals. Listening device 104 may be configured to provide audio captured by microphone 112A as an audio data signal to one or more of switching device 102, consumer electronic device 106, and/or user device 110 to enable processing of the audio data signals. User device 110 may be configured to provide audio captured by microphone 112B as an audio data signal to one or more of switching device 102, listening device 104, and/or consumer electronic device 106 to enable processing of the audio data signals. For instance, listening device 104 and/or user device 110 may provide audio captured by respective microphones 112A and/or 112B to switching device 102, listening device 104, consumer electronic device 106, and/or user device 110 to enable a user to interact, view, search, and/or select content, and/or perform functions related to audio input features of one or more of switching device 102, listening device 104, consumer electronic device 106, user device 110, and/or an application executed by switching device 102, listening device 104, consumer electronic device 106, and/or user device 110.

To help further illustrate techniques for calibrating a media presentation device and/or a microphone via event detection, FIG. 2 will now be described. FIG. 2 is a block diagram of a media system 200 (“system 200” hereinafter) configured to calibrate a media presentation device and/or a microphone via event detection, according to an exemplary embodiment. As shown in FIG. 2, system 200 includes a switching device 202, a remote control device 204A, a smart home device 204B, a plurality of consumer electronic devices 206A-206D, and one or more speakers 208 (“speakers 208” hereinafter). Switching device 202 is a further example of switching device 102, remote control device 204A and smart home device 204B are further examples of listening device 104, and consumer electronic devices 206A-206D and speakers 208 are further examples of consumer electronic device 106, as respectively described with respect to FIG. 1.

Consumer electronic devices 206A-206C are configured to provide media content signals (e.g., media content signals 214A, 214B, and 214C, respectively) for playback and are referred to as “source” devices. Consumer electronic device 206D is configured to receive media content signals (e.g., media content signals 216) and is referred to as a media presentation device and/or a “sink” device. Consumer electronic device 206D is coupled to one or more speakers 208. Speakers 208 may be incorporated in consumer electronic device 206D, or alternatively, may be part of an external sound system that is coupled to consumer electronic device 206D and/or switching device 202. In an embodiment in which speakers 208 are part of an external sound system, speakers 208 may be communicatively coupled to consumer electronic device 206D via a wired interface (e.g., an HDMI cable, an optical cable, a universal serial bus (USB) cable, an Ethernet cable, etc.) or a wireless interface (e.g., Bluetooth, Wi-Fi, etc.).

As shown in FIG. 2, consumer electronic device 206A is coupled to a first port 210A of switching device 202, consumer electronic device 206B is coupled to a second port 210B of switching device 202, consumer electronic device 206C is coupled to a third port 210C of switching device 202, and consumer electronic device 102D is coupled to a fourth port 210D of switching device 204. In accordance with an embodiment, ports 210A-210D are HDMI ports; however, embodiments described herein are not so limited. As further shown in FIG. 2, consumer electronic device 206A is a Blu-ray player, consumer electronic device 206B is a set-top box, consumer electronic device 206C is a streaming media player, and consumer electronic device 206D is a TV. Examples of a streaming media device include, but are not limited to, a Roku™ device, an AppleTV™ device, a Chromecast™, and/or the like. The depiction of these particular electronics devices is merely for illustrative purposes. It is noted that while FIG. 2 shows that switching device 202 includes four ports 210A-210D, switching device 202 may include any number of ports, and therefore, may be coupled to any number of consumer electronic devices. As described with respect to FIG. 2, ports 210A-210D are ports for receiving and/or providing media content signals (e.g., AV ports); however, switching device 202 may include other types of ports (not shown in FIG. 2), such as, but not limited to, input/output (IO) ports, network ports, and/or the like.

Switching device 202 is configured to select (e.g., switch between) different audio and/or video source devices that are coupled to ports 210A-210C (e.g., consumer electronic device 206A, consumer electronic device 206B or consumer electronic device 206C) and provide an output signal (e.g., media content signals 216) comprising audio and/or video signals (e.g., media content signals 214A, media content signals 214B or media content signals 214C) provided by the selected media content source device. Media content signals 216 are provided to consumer electronic device 206D that is coupled to port 210D. Media content signals 216 may also be provided to any other device capable of playing back audio and/or video signals (e.g., speaker(s) 208) that may be coupled consumer electronic device 206D and/or to port 206D and/or other port(s) (not shown) of switching device 202.

Remote control device 204A may be operable to control any or all of switching device 202, consumer electronic devices 206A-206D, and/or speakers 208. Types of remote control device 204A include, but are not limited to, infrared (IR) remote controllers, Bluetooth controllers, mobile phones, universal remotes, and/or the like. As shown in FIG. 2, system 200 includes one remote control device 204A. Alternatively, multiple remote control devices may be used. For instance, each of switching device 202, consumer electronic devices 206A-206D, and/or speakers 208 may be controlled via a respective remote control device.

Smart home device 204B is operable to perform one or more smart home functions with respect to system 200. In accordance with an embodiment, smart home device 204B is operable to control any or all of switching device 202, consumer electronic devices 206A-206D, and/or speakers 208. Types of smart home device 204B include, but are not limited to, smart plugs, smart speakers, smart thermostats, smart appliances, smart TVs, smart device hubs (e.g., smart devices for coordinating and/or controlling other smart home devices), and/or the like. As shown in FIG. 2, system 200 includes one smart home device 204B. Alternatively multiple smart home devices may be used. Furthermore, functions of smart home device 204B may be integrated into one or more of switching device 202 and/or consumer electronic devices 206A-206D. For instance, consumer electronic device 206D may be a smart TV with smart home functions.

As shown in FIG. 2, remote control device 204 includes a microphone 212A and smart home device 204B includes a microphone 212B. Microphone 212A and microphone 212B are further examples of microphone 112A, as described with respect to FIG. 1. Microphone 212A and microphone 212B are each configured to capture audio signals. Remote control device 204A and/or smart home device 204B may be configured to provide audio data signals representative of captured audio signals to one or more of switching device 202, consumer electronic devices 206A-206D, and/or speakers 208 to enable a user to interact, view, search, and/or select content, and/or perform functions related to audio input features of one or more of switching device 202, consumer electronic devices 206A-206D, speakers 208, and/or an application executed by switching device 202, consumer electronic devices 206A-206D, and/or speakers 208. Alternatively, or additionally, remote control device 204A and/or smart home device 204B may be configured to provide respective audio data signals to a computing device of another user (e.g., user device 110 of FIG. 1).

Switching device 202 may be configured to calibrate media presentation devices (e.g., consumer electronic device 206D, speakers 208, or another media presentation device of system 200 (e.g., a media presentation device not shown in FIG. 2)), microphone 212A, microphone 212B, and/or a microphone of a remotely located computing device (e.g., microphone 112B of user device 110 of FIG. 1). For example, switching device 202 may analyze an audio data signal captured by microphone 212 and determine whether to adjust one or more of a volume setting of speakers 208 and/or a gain setting of microphone 212. Switching device 202 transmits a command to one or more of speakers 208, consumer electronic devices 206A-206D, and/or remote control device 204. In accordance with an embodiment, the command includes instructions to adjust one or more of the volume setting of speakers 208 and/or the gain setting of microphone 212.

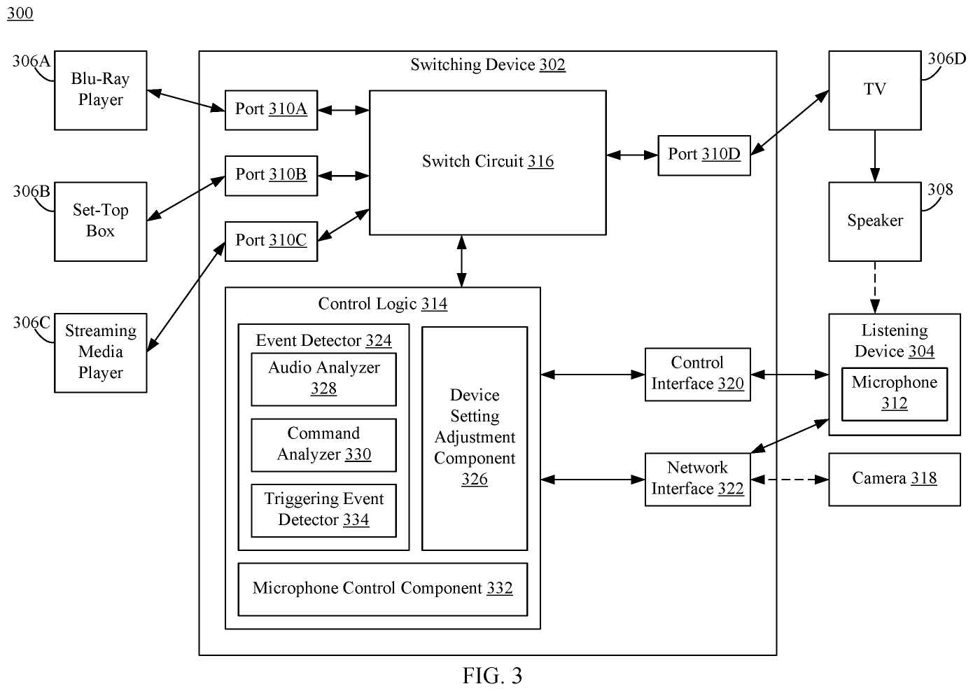

Turning now to FIG. 3, a block diagram of a media system 300 (“system 300” hereinafter) configured to calibrate a media presentation device or a microphone via event detection, according to another exemplary embodiment, is shown. System 300 is an example of system 200, as described above with reference to FIG. 2. System 300 includes a switching device 302, a listening device 304, a plurality of consumer electronic devices 306A-306D, one or more speakers 308 (“speakers 308” hereinafter), and camera 318. Consumer electronic devices 306A-306D and speakers 308 may be respective examples of consumer electronic devices 206A-206D and speakers 208 of FIG. 2. Any of consumer electronic devices 306A-306D and/or speakers 308 may be any electronic device capable of providing and/or playing back AV signals.

Listening device 304 may be an example of listening device 104, as described in reference to FIG. 1, or remote control device 204A or smart home device 204B, as respective described in reference to FIG. 2. As shown in FIG. 3, listening device 304 includes a microphone 312, which may be an example of microphone 112, as described above in reference to FIG. 1, or microphone 212A or 212B, as described above in reference to FIG. 2. Listening device 304 may be a remote control device associated with switching device 302, a remote control device associated with any of consumer electronic devices 306A-306D or speakers 308, a universal remote, a smart phone, a smart home device, and/or any other type of listening device, as described elsewhere herein.

Switching device 302 may be an example of switching device 202, as described above in reference to FIG. 2. As shown in FIG. 3, switching device 302 includes (e.g., AV) ports 310A-310D, control logic 314, switch circuit 316, control interface 320, and network interface 322. As further shown in FIG. 3, consumer electronic device 306A is coupled to port 310A, consumer electronic device 306B is coupled to port 310B, consumer electronic device 306C is coupled to port 310C, and consumer electronic device 306D is coupled to port 310D. Ports 310A-310C may be automatically configured to be source AV ports, and port 310D may be automatically configured to be a sink AV port. Ports 310A-30D may include one or more HDMI ports, although the embodiments described herein are not so limited.

Switch circuit 316 may be implemented as hardware (e.g., electrical circuits), or hardware that executes one or both of software (e.g., as executed by a processor or processing device) and firmware. Switch circuit 316 is configured to operate and perform functions according to the embodiments described herein. For example, switch circuit 316 is configured to provide switched connections between ports 310A-310C and port 310D. That is, switch circuit 316 may receive input media content signals from source devices (e.g., consumer electronic devices 306A-306C via ports 310A-310C) and provide output media content signals to media presentation devices (e.g., consumer electronic device 306A via port 310D). Switch circuit 316 may comprise one or more switch circuit portions (e.g., comprising one or more switches/switching elements) and may be combined or used in conjunction with other portions of system 300.

Control logic 314 is configured to control switch circuit 316, receive signals from devices coupled to switching device 302 (e.g., from consumer electronic devices 306A-306D (e.g., via switch circuit 316), from listening device 304 (e.g., via control interface 320 and/or network interface 322), from speakers 308 (e.g., via switch circuit 316 and/or via microphone 312 (e.g., via control interface 320 and/or network interface 322)), from camera 318 (e.g., via network interface 322), from user device 110 of FIG. 1 (e.g., via network interface 322), and/or another device not show in FIG. 3 for brevity), receive signals from components of switching device 302 (e.g., switch circuit 316, control interface 320, and/or network interface 322), and/or provide signals to devices coupled to switching device 302 and/or to components of switching device 302. For example, control logic 314 in accordance with an embodiment is configured to receive audio data signals from listening device 304, the audio data signal representative of audio played back by speakers 308 and captured by microphone 312. In another example embodiment, control logic 314 is configured to receive a command signal from a computing device (e.g., user device 110 of FIG. 1) via network interface 322. As shown in FIG. 3, control logic 314 includes an event detector 324, a device setting adjustment component 326, and a microphone control component 332.

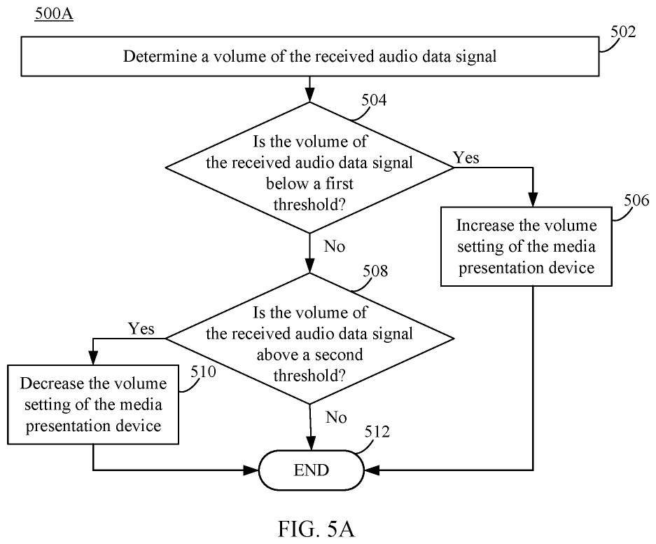

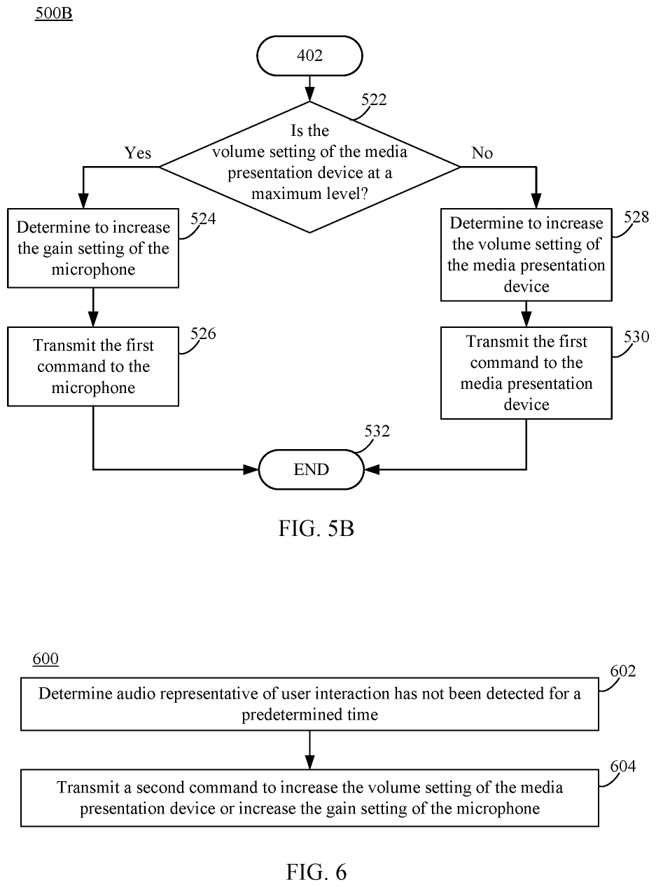

Event detector 324 is configured to analyze signals received by switching device 302 and detect events based on the results of the analysis. As shown in FIG. 3, event detector 324 comprises an audio analyzer 328, a command analyzer 330, and a triggering event detector 334. Audio analyzer 328 is configured to analyze audio data signals received from listening device 304 (e.g., audio data signals representative of audio played back by speakers 308 and captured by microphone 312) and detect an adjustment event based on the results of the analysis. In this context, an “adjustment event” is an event that, when detected by event detector 324, causes control logic 314 (or a subcomponent of control logic 314) to adjust a volume setting of a media presentation device and/or a gain setting of a microphone. Audio analyzer 328 may be configured to analyze audio data signals received from listening device 304 to detect adjustment events in various ways. For instance, in accordance with one or more embodiments, audio analyzer 328 is configured to determine a volume of the received audio data signals. In accordance with another one or more embodiments, audio analyzer 328 is configured to compare the received audio data signals with an expected audio output of a media presentation device (e.g., a source device and/or speakers 308). For example, in accordance with another embodiment, audio analyzer 328 is configured to compare the received audio data signals with a reference audio data signal (e.g., an audio data signal of media content, an audio tone, an audio pattern, and/or the like). In such an example, the reference audio data signal may be stored as an audio file (e.g., in memory of switching device 302 or in an external memory device accessible to switching device 302). Additional details regarding analyzing audio data signals received from a remote control device will be described with respect to FIGS. 4A, 4C, and 5A, as well as elsewhere herein.

Command analyzer 330 is configured to analyze command signals received from computing devices over a network (e.g., user device 110 of FIG. 1 over network 108 via network interface 322) and detect an adjustment event based on the results of the analysis. Command analyzer 330 may be configured to analyze command signals received from computing devices in various ways, in embodiments. For instance, in accordance with an embodiment, command analyzer 330 analyzes instructions included in the command signal to determine if the instructions relate to adjusting a volume setting of a media presentation device and/or a gain setting of a microphone. Additional details regarding analyzing audio data signals received from a remote control device will be described with respect to FIGS. 4A and 4B, as well as elsewhere herein.

Triggering event detector 334 is configured to detect a triggering event. Examples of triggering events include, but are not limited to, detecting an incoming audio or video call, detecting an outgoing audio or video call, detecting an indication that an audio input/output feature of an application has been enabled, detecting that an application is in a state to accept user input, detecting that an application with audio input/output features has been launched, and/or the like. In accordance with one or more embodiments, triggering event detector 334 detects a triggering event based at least on an analysis of data (e.g., signals received by control logic 314). For example, in accordance with an embodiment, triggering event detector 334 detects a triggering event based at least on an analysis of media content signals provided by one or more source devices (e.g., consumer electronic devices 306A-306C) and/or provided to one or more media presentation devices (e.g., consumer electronic device 306D and/or speakers 308). For instance, triggering event detector 334 may access media content signals via switch circuit 316, analyze the accessed media content signals, and detect a triggering event based at least on the analyzed media content signals. In accordance with another embodiment, triggering event detector 334 detects a triggering event based at least on an analysis of audio data signals (e.g., performed by audio analyzer 328), the audio data signals received from listening device 304 (e.g., via control interface 320 or network interface 322), the audio data signals representative of audio played back by speakers 308 and captured by microphone 312. In accordance with another embodiment, triggering event detector 334 detects a triggering event based at least on an analysis of video signals generated by camera 318. In accordance with an embodiment, subsequent to detecting a triggering event, triggering event detector 334 causes audio analyzer 328 to analyze an audio signal and/or command analyzer 330 to analyze a command signal. Additional details regarding detecting triggering events will be discussed below with respect to FIG. 9.

Device setting adjustment component 326 is configured to determine whether to adjust one or more of a volume setting of speakers 308 and/or a gain setting of microphone 312 based at least on the adjustment event detected by event detector 324. Additional details regarding determining whether to adjust volume settings of a media presentation device and/or gain settings of a microphone will be discussed further with respect to FIGS. 4A, 4B, 4C, 5A, 5B, and 6, as well as elsewhere herein.

Device setting adjustment component 326 is further configured to transmit a command to one or more of listening device 304, consumer electronic device 306D, speakers 308, and/or a remotely located computing device (e.g., user device 110 of FIG. 1) responsive to the determinations described above. The command includes instructions to adjust one or more of a volume setting of consumer electronic device 306D and/or speakers 308 (or another media presentation device) and/or the gain setting of microphone 312 and/or a microphone of the remotely located computing device (e.g., microphone 112B of FIG. 1). For example, suppose device setting adjustment component 326 determines the volume of the received audio data signal is too low (or too high) and/or the received command signal includes instructions to increase (or decrease) the volume setting of speakers 308. In this context, device setting adjustment component 326 transmits a command to consumer electronic device 306D via switch circuit 316 and port 310D. This command includes instructions to increase (or decrease) the volume setting of speakers 308 communicatively coupled to consumer electronic device 306D. In response to receiving the command, consumer electronic device 306D adjusts the volume setting of speakers 308 (e.g., via control logic of consumer electronic device 306D and/or transmitting instructions to speakers 308).

In another example scenario, suppose device setting adjustment component 326 determines the gain and/or sensitivity of microphone 312 is too low (or too high) based on the analysis performed by audio analyzer 328 (e.g., the volume of the analyzed audio data signal is too high or too low, the analyzed audio data signal includes too much noise, the analyzed audio data signal does not include detectable audio corresponding to audio played by the media presentation device (e.g., speakers 308), and/or the like). In this context, device setting adjustment component 326 transmits a command to listening device 304 via control interface 320 (or network interface 322). This command includes instructions to increase (or decrease) a gain setting of microphone 312 and/or a sensitivity setting of microphone 312. In response to receiving the command, listening device 304 increases (or decreases) the gain setting and/or the sensitivity setting of microphone 312 (e.g., via control logic of listening device 304, not shown in FIG. 3). As discussed further with respect to microphone control component 332, microphone control component 332 may transmit commands to listening device 304 on behalf of device setting adjustment component 326, in embodiments.

In another example scenario, suppose device setting adjustment component 326 determines the gain and/or sensitivity of a microphone of a remotely located computing device (e.g., microphone 112B of computing device 110 of FIG. 1) is too low (or too high) based on the analysis performed by audio analyzer 328 and/or the analysis performed by command analyzer 330. In this context, device setting adjustment component 326 transmits a command to the remotely located computing device via network interface 322. This command includes instructions to increase (or decrease) a gain and/or sensitivity setting of the microphone of the remotely located device. In response to receiving the command, the remotely located device increases (or decreases) the gain setting and/or the sensitivity setting of microphone 312. As further with respect to microphone control component 332, microphone control component 332 may transmit commands to remotely located computing devices on behalf of device setting adjustment component 326, in embodiments.

In some embodiments, device setting adjustment component 326 may transmit respective commands to the media presentation device and/or the microphone (e.g., of the listening device and/or the remotely located computing device) based at least on the analysis of the same audio data signal and/or command signal. Additional details regarding transmitting commands to a media presentation device and/or a remote control device will be discussed further below with respect to FIGS. 4A, 5A, 5B, 6, and 8B.

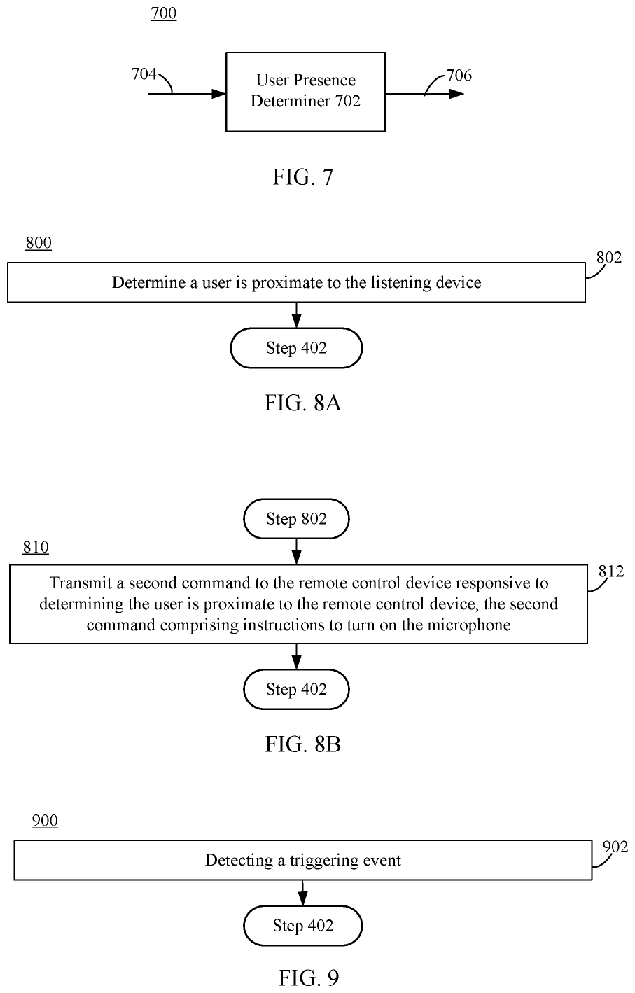

Microphone control component 332 is configured to control microphone 312 and/or a microphone of a remotely located computing device (e.g., microphone 112B of FIG. 1). For example, microphone control component 332 is configured to transmit commands to listening device 304 on behalf of device setting adjustment component 326 (e.g., via control interface 320 or network interface 322) to adjust a gain setting and/or a sensitivity setting of microphone 312. Alternatively, or additionally, microphone control component 332 is configured to transmit commands to a remotely located computing device (e.g., user device 110 of FIG. 1) on behalf of device setting adjustment component 326 (e.g., via network interface 322) to adjust a gain setting and/or a sensitivity setting of a microphone of the device (e.g., microphone 112B of FIG. 1). Furthermore, microphone control component 328 may be configured to determine whether or not to turn on (or turn off) microphone 312 (and/or a microphone of a remotely located computing device) and transmit commands to listening device 304 (and/or the remotely located computing device) to turn on (or turn off) microphone 312 (and/or the microphone of the remotely located computing device) (e.g., via control interface 320 or network interface 322). For example, microphone control component 328 may determine whether or not to turn on or off (or otherwise enable or disable processing of audio captured by) microphone 312 based on one or more of a triggering event detected by triggering event detector 334, a detection of a user's presence (e.g., as described further with respect to FIGS. 7 and 8A), a power state of microphone 312, and/or any other detection, determination, analysis, and/or command described elsewhere herein. Additional details regarding determining to enable processing of audio captured by a microphone based on a user's presence are described with respect to FIG. 8B, as well as elsewhere herein.

Control logic 314 may include other components not shown in FIG. 3. For example, control logic 314 in accordance with one or more embodiments includes an identification component, one or more mapping components, an action determination component, and/or an integrated microphone. An identification component in accordance with an embodiment is configured to identify consumer electronic devices 306A-306D coupled to each of ports 310A-310D, determine identifier(s) thereof (e.g., a type of device (e.g., a DVD player, a Blu-ray player, a video game console, a streaming media device, a TV, an HDTV, a projector, a speaker, etc.), a brand name of the device, a manufacturer of the device, a model number of the device, etc.), and/or provide identifier(s) to one or more mapping components. A mapping component in accordance with an embodiment is configured to determine a device-to-port mapping (e.g., based on identifier(s) received from an identification component). For example, a mapping component may generate a data structure (e.g., a table, a map, an array, etc.) that associates identifier(s) for any given identified device to the port to which that device is coupled (e.g., consumer electronic device 306A is a Blu-ray player coupled to port 310A, consumer electronic device 306B is a set-top box coupled to port 310B, consumer electronic device 306C is a streaming media player coupled to port 310C, and consumer electronic device 306D is a TV coupled to port 310D, as shown in FIG. 3). An action determination component in accordance with an embodiment is configured to perform actions with respect to particular consumer electronic device (e.g., toggle power (i.e., to turn it off or on), issue an operational command (e.g., “play” or “pause”, adjust (e.g., volume) settings), transmit a notification message, and/or automatically cause switch circuit 316 to connect a first port to which a particular source device (e.g., any of consumer electronic devices 306A-306C) is connected to a second port to which a particular sink device (e.g., consumer electronic device 306D) is connected. In accordance with an embodiment, an action determination component determines actions to be performed based on another mapping component that maps particular actions to one or more particular consumer electronic devices. An integrated microphone in accordance with an embodiment is configured to capture audio played back by a media presentation device (e.g., speakers 308). For instance, audio captured by the integrated microphone may be analyzed by audio analyzer 328 for providing to microphone control component 332 to determine whether or not to turn on (or turn off) microphone 312.

Control interface 320 may comprise a receiver configured to receive wireless control signals from a device (e.g., listening device 304, camera 318, a computing device configured to control switching device 304, consumer electronic device(s) 306A-306D, speakers 308, etc.). Control interface 320 may be configured to receive, detect, and/or sniff wireless control signals from a plurality of different remote control devices (e.g., including listening device 304), for example, a dedicated remote control device configured to control switching device 302, or dedicated remote control devices each configured to control a respective device of consumer electronic device(s) 306A-306D and/or speakers 308. For instance, control interface 320 may comprise a wireless receiver configured to receive control signals transmitted from a remote control device (e.g., listening device 304) via an IR-based protocol, an RF-based protocol, and/or an IP-based protocol. Upon detecting control signals, control interface 320 analyzes the control signals to identify one or more identifier(s) therein that uniquely identify the consumer electronic device for which the control signals are intended (e.g., consumer electronic device(s) 306A-306D and/or speakers 308). Control interface 320 may further determine a command (e.g., a toggle power-on/power-off command, play, fast-forward, pause, rewind, etc.) included in the control signals. As discussed elsewhere herein, control interface 320 may also be configured to transmit commands from microphone control component 332 to listening device 304 to adjust (e.g., increase or decrease) a gain setting of, adjust a sensitivity setting of, turn on, or turn off microphone 312. Furthermore, control interface 320 may also be configured to transmit audio data signals captured by microphone 312 from listening device 304 to control logic 314.

Network interface 322 is configured to interface with remote sites or one or more networks (e.g., network 108 of FIG. 1) and/or devices via wired or wireless connections. Examples of networks include, but are not limited to, local area networks (LANs), wide area networks (WANs), the Internet, etc. In a particular example, and as shown in FIG. 3, camera 318 is coupled to switching device 302 via network interface 322. In another example, network interface 322 enables accessing data from a smart home application. In another example, a remotely located computing device (e.g., computing device 110 of FIG. 1) is communicatively coupled to switching device 302 over a network via network interface 322.

Camera 318 is a camera located proximate to a media presentation device (e.g., consumer electronic device 306D or speakers 308) and/or a user such that it can capture video or images thereof. As shown in FIG. 3, camera 318 may be a camera device external to switching device 302, listening device 304, and consumer electronic devices 306A-306D. In accordance with another embodiment, camera 318 is incorporated in a device (e.g., switching device 302, listening device 304, consumer electronic devices 306A-306D, etc.). As shown in FIG. 3, camera 318 sends signals to and/or receives signals from switching device 302 via network interface 322, but the embodiments disclosed herein are not so limited. For instance, camera 318 may be communicatively coupled to a port of switching device 302 (e.g., as a built-in camera of one of consumer electronic devices 306A-306D or a standalone camera coupled to a port not shown in FIG. 3), send signals to and/or receive signals from switching device 302 via control interface 320 (e.g., as a camera of listening device 304 or a standalone camera). Examples of camera 318 include, but are not limited to, a webcam, a security camera, a built-in camera, and/or the like. Camera 318 is configured to capture and/or record images and/or videos and generate a video data signal. The video data signal is provided to triggering event detector 334 (e.g., for detecting a triggering event based on the generated video data signal) and/or a component configured to determine a user's presence (as described further with respect to FIGS. 7, 8A, and 8B).

Accordingly, in embodiments, switching device 302 of FIG. 3 may calibrate a media presentation device and/or a microphone via event detection in various ways. For example, FIG. 4A is a flowchart 400 of a process for media presentation device or microphone calibration via event detection, according to an exemplary embodiment. Switching device 302 may operate to perform the steps of flowchart 400 in an embodiment. Not all steps of flowchart 400 need be performed in all embodiments. Other structural and operational embodiments will be apparent to persons skilled in the relevant art(s) based on the following discussion of FIG. 4A with respect to FIG. 3.

Flowchart 400 begins with step 402. In step 402, an adjustment event is detected based on an analysis of a received signal. For instance, event detector detects an adjustment event based on an analysis of a signal received by switching device 302. Examples of signals event detector (or a component thereof) may analyze to detect an adjustment event include, but are not limited to, media content signals (e.g., by accessing switch circuit 316), audio data signals received from listening device 304, command signals received from a remotely located computing device (e.g., via network interface 322), and/or video data signals received from camera 318. Further details regarding detecting events based on an analysis of a command signal are described with respect to FIG. 4B, as well as elsewhere herein. Further details regarding detecting events based on an analysis of an audio data signal are described with respect to FIG. 4C, as well as elsewhere herein.

In step 404, a determination to adjust at least one of a volume setting of the media presentation device and/or a gain setting (and/or a sensitivity setting) of a microphone is made based at least on the detected adjustment event. For example, device setting adjustment component 326 of FIG. 3 determines whether to adjust at least one of a volume setting of speakers 308, a gain setting (or a sensitivity setting) of microphone 312, and/or a gain setting (or a sensitivity setting) of a microphone of a remotely located computing device (e.g., microphone 112B of FIG. 1) based at least on the adjustment event detected in step 402. In some embodiments, device setting adjustment component 326 determines to adjust at least one of the volume setting of speakers 308, the gain setting of microphone 312, and/or the gain setting of a microphone of a remotely located computing device based on the results of an analysis of audio data signals by audio analyzer 328. Additional details regarding analyzing audio data signals are discussed with respect to FIG. 4C, as well as elsewhere herein. Additional details regarding determining to adjust at least one of the volume setting of speakers 308, the gain setting of microphone 312, or the gain setting of a microphone of a remotely located computing device are discussed further with respect to FIGS. 5A and 5B, as well as elsewhere herein.

In step 406, responsive to the determination, a first command is transmitted to at least one of the media presentation device or the microphone. For example, in response to the determination made in step 404, device setting adjustment component 326 of FIG. 3 transmits a first command to at least one of consumer electronic device 306D, speakers 308, microphone 312, and/or the microphone of the remotely located computing device (e.g., microphone 112B of FIG. 1). For instance, if device setting adjustment component 326 determines in step 404 to adjust a volume setting of speakers 308, device setting adjustment component 326 transmits a first command to speakers 308 (e.g., via switch circuit 316 and port 310D to consumer electronic device 306D, via control interface 320, or via network interface 322), the first command including instructions to adjust (e.g., increase or decrease) the volume setting of speakers 308. If device setting adjustment component 326 determines in step 404 to adjust a gain setting of microphone 312, device setting adjustment component 326 transmits a first command to listening device 304 (e.g., via microphone control component 332 and control interface 320 (or network interface 322)), the first command including instructions to adjust (e.g., increase or decrease) the gain setting of microphone 312. If device setting adjustment component 326 determines in step 404 to adjust a gain setting of a microphone of a remotely located computing device, device setting adjustment component 326 transmits a first command to the remotely located computing device (e.g., over network 108 via network interface 322), the first command including instructions to adjust (e.g., increase or decrease) the gain setting of the microphone. In accordance with an embodiment, device setting adjustment component 326 transmits multiple commands to multiple devices. For instance, device setting adjustment component 326 in a non-limiting example transmits a first command to listening device 304 that includes instructions to adjust the gain setting of microphone 312 and transmits a second command to speakers 308 (or consumer electronic device 306D) to adjust the volume setting of speakers 308.

As described herein, event detector 324 is configured to detect an adjustment event based on an analysis of a received signal. Event detector 324 may analyze signals in various ways to detect an adjustment signal, in embodiments. For example, FIG. 4B is a flowchart 410 of a process for detecting an adjustment event based on an analysis of a command signal, according to an example embodiment. Flowchart 410 is a further embodiment of step 402 of flowchart 400 of FIG. 4A. Switching device 302 may operate to perform the steps of flowchart 410 in an embodiment. Not all steps of flowchart 410 need be performed in all embodiments. Other structural and operational embodiments will be apparent to persons skilled in the relevant art(s) based on the following discussion of FIG. 4B with respect to FIG. 3.

Flowchart 410 begins with step 412. In step 412, a command signal is received from a computing device via a network interface. The command signal comprises instructions to adjust a volume setting of a media presentation device. For example, command analyzer 330 of FIG. 3 receives a command signal from user device 110 (not shown in FIG. 3) via network interface 322. The command signal comprises instructions to adjust a volume setting of a media presentation device of system 300 (e.g., consumer electronic device 306D, speakers 308, or another media presentation device of system 300).

In step 414, an adjustment event is detected based on an analysis of the command signal. For example, command analyzer 330 analyzes the command signal received in step 412 and detects an adjustment event. In accordance with an embodiment, to detect the adjustment event, command analyzer 330 analyzes the instructions included in the command signal and determines the instructions correspond to an adjustment event. As stated above, event detector 324 may analyze signals in various ways to detect an adjustment signal, in embodiments. For example, FIG. 4C is a flowchart 420 of a process for detecting an adjustment event based on an analysis of an audio data signal, according to an example embodiment. Flowchart 420 is a further embodiment of step 402 of flowchart 400 of FIG. 4A. Switching device 302 may operate to perform the steps of flowchart 410 in an embodiment. Not all steps of flowchart 410 need be performed in all embodiments. Other structural and operational embodiments will be apparent to persons skilled in the relevant art(s) based on the following discussion of FIG. 4C with respect to FIG. 3.

Flowchart 420 begins with step 422. In step 422, an audio data signal is received from a listening device. For example, audio analyzer 328 of FIG. 3 receives an audio data signal from listening device 304 via control interface 320. In accordance with an embodiment, the audio data signal is representative of audio played back by speakers 308 and captured by microphone 312.

In step 424, an adjustment event is detected based on an analysis of the audio data signal. For example, audio analyzer 328 of FIG. 3 detects an adjustment event based on an analysis of the audio data signal received in step 422. In accordance with an embodiment, audio analyzer 328 of FIG. 3 analyzes the received audio data signal to determine one or more characteristics (e.g., volume, frequency, frequency bandwidth, power level, voltage level, nominal level, etc.) of the audio data signal. Audio analyzer 328 may detect an adjustment event by comparing a measure of one or more of the determined characteristics with one or more thresholds. Such thresholds may include, but are not limited to, a predetermined threshold set by a manufacturer of the device, a predetermined threshold set by a user associated with the device, and/or the like. In accordance with one or more embodiments, such a user may adjust the predetermined thresholds via a user interface of an application associated with switching device 302 or the remotely located computing device. Such a user interface may be presented via consumer electronic device 306D, listening device 304, a computing device (e.g., a computer or mobile phone) of the user, and/or the like. In accordance with an embodiment, audio analyzer 328 provides the results of the performed analysis to device setting adjustment component 326 and flowchart 420 proceeds to step 404 of flowchart 400 of FIG. 4A.

Audio analyzer 328 and device setting adjustment component 326 of FIG. 3 may be respectively configured to analyze audio data signals received from listening device 304 and determine whether to adjust one or more of a volume setting of a media presentation device (e.g., speakers 308) and/or a gain setting of microphone 312 in various ways, in embodiments. For instance, device setting adjustment component 326 may determine to calibrate speakers 308 by adjusting a volume setting of speakers 308 based at least on the analysis performed by audio analyzer 328. For example, FIG. 5A is a flowchart 500A of a process for media presentation device calibration via event detection, according to an exemplary embodiment. Switching device 302 may operate to perform the steps of flowchart 500A in an embodiment. Not all steps of flowchart 500A need be performed in all embodiments. Other structural and operational embodiments will be apparent to persons skilled in the relevant art(s) based on the following discussion of FIG. 5A with respect to FIGS. 3, 4A, and 4C.

Flowchart 500A begins with step 502, which may be a subset of step 424 of flowchart 420 of FIG. 4C. In step 502, a volume of the received audio data signal is determined. For example, audio analyzer 328 of FIG. 3 in accordance with an embodiment analyzes the audio data signal received from listening device 304 in step 422 of flowchart 420 to determine a volume of the audio data signal. For instance, audio analyzer 328 may be configured to analyze the received audio data signal to determine a volume measured in decibels.

Flowchart 500A continues to step 504, which may be a subset of step 424 of flowchart 420 of FIG. 4C. In step 504, a determination of whether the volume of the received audio data signal is below a first threshold is made. For example, audio analyzer 328 of FIG. 3 in accordance with an embodiment determines whether the volume determined in step 502 is below a first threshold. In embodiments, the first threshold may be a predetermined threshold set by a manufacturer of switching device 302 and/or a user associated with switching device 302, listening device 304, consumer electronic devices 306A-306D, and/or speaker 308. In accordance with one or more embodiments, such a user may adjust the predetermined thresholds via a user interface of an application associated with switching device 302. In accordance with an embodiment, the first threshold is a set value (e.g., in decibels) that audio analyzer 328 compares with the determined volume (e.g., in decibels). If the volume is below the first threshold, audio analyzer 328 detects an adjustment event and provides an indication to device setting adjustment component 326 and flowchart 500A continues to step 506. Otherwise, flowchart 500A continues to step 508.

Step 506 may be a subset of steps 404 and 406 of flowchart 400 of FIG. 4A. In step 506, the volume setting of the media presentation device is increased. For example, device setting adjustment component 326 of FIG. 3 determines to increase the volume setting of speaker 308 (or consumer electronic device 306D or another media presentation device) and transmits a command to speaker 308 (or consumer electronic device 306D or another media presentation device), the command including instructions to increase the volume setting of speakers 308 (or consumer electronic device 306D or another media presentation device). In accordance with an embodiment, the instructions specify an increment to increase the volume setting by. In accordance with an embodiment, device setting adjustment component 326 determines the increment to increase the volume setting by based at least on a difference between the first threshold and the determined volume of the received audio data signal. After the volume setting of the media presentation device is increased, flowchart 500A continues to step 512.

Step 508 may be a subset of step 424 of flowchart 420 of FIG. 4C. In step 508, a determination of whether the volume of the received audio data signal is above a second threshold is made. The second threshold is greater than the first threshold. For example, audio analyzer 328 of FIG. 3 in accordance with an embodiment determines whether the volume determined in step 502 is above a second threshold. In embodiments, the second threshold may be a predetermined threshold set in a manner similar to those described with respect to the first threshold. In accordance with an embodiment, the second threshold is a set value (e.g., in decibels) that audio analyzer 328 compares with the determined volume (e.g., in decibels). If the volume is above the second threshold, audio analyzer 328 detects an adjustment event and provides an indication to device setting adjustment component 326 and flowchart 500A continues to step 510. Otherwise, flowchart 500A continues to step 512.

Step 510 may be a subset of steps 404 and 406 of flowchart 400 of FIG. 4A. In step 510, the volume setting of the media presentation device is decreased. For example, device setting adjustment component 326 of FIG. 3 determines to decrease the volume setting of speaker 308 (or consumer electronic device 306D or another media presentation device) transmits a command to speaker 308 (or consumer electronic device 306D or another media presentation device), the command including instructions to decrease the volume setting of speakers 308 (or consumer electronic device 306D or another media presentation device). In accordance with an embodiment, the instructions specify an increment to decrease the volume setting by. In accordance with an embodiment, device setting adjustment component 326 determines the increment to decrease the volume setting by based at least on a difference between the second threshold and the determined volume of the received audio data signal. After the volume setting of the media presentation device is decreased, flowchart 500A continues to step 512.

Flowchart 500A ends with step 512. In accordance with an embodiment, step 512 includes receiving a subsequent audio data signal from remote control device 312 of FIG. 3. In this context, switching device 302 is configured to repeat one or more of steps 502-510 (as well as any additional analysis of the subsequent audio data signal and/or determinations based on the additional analysis) to determine if the volume is within an acceptable range (i.e., at or above the first threshold and at or below the second threshold).

Flowchart 500A has been described above with respect to adjusting the volume setting of a media presentation device (e.g., speakers 308, consumer electronic device 306D, and/or the like). It is also contemplated herein that similar methods may be used to adjust the gain setting of a microphone (e.g., microphone 112B of FIG. 1 and/or microphone 312 of FIG. 3). For instance, if the determined volume of the audio data signal is below the first threshold, device setting adjustment component 326 may transmit a command to listening device 304 (in addition to or alternatively to the command transmitted in step 506), the command including instructions to increase the gain setting of microphone 312 and/or microphone 112B. For example, and as described further with regard to FIG. 5B as well as elsewhere herein, if the volume setting of the media presentation is at a maximum level, device setting adjustment component 326 determines to increase the gain setting of a microphone and transmits a command to the microphone (or a device comprising the microphone (e.g., user device 110 or listening device 304) to cause the gain setting of the microphone to increase. Furthermore, if the determined volume of the audio data signal is above the second threshold, device setting adjustment component 326 may transmit a command to listening device 304 (in addition to or alternatively to the command transmitted in step 510), the command including instructions to decrease the gain setting of microphone 312 and/or microphone 112B.

As noted with respect to FIG. 5A, device setting adjustment component 326 of FIG. 3 may determine whether to adjust a volume setting or a gain setting. Device setting adjustment component 326 may operate in various ways to determine whether to adjust the volume setting or the gain setting, in embodiments. For example, FIG. 5B is a flowchart 500B of a process for determining to adjust a volume setting or a gain setting, according to an exemplary embodiment. Device setting adjustment component 326 may operate to perform the steps of flowchart 500B in an embodiment. Not all steps of flowchart 500B need be performed in all embodiments. Other structural and operational embodiments will be apparent to persons skilled in the relevant art(s) based on the following discussion of FIG. 5B with respect to FIGS. 3 and 4A.

Flowchart 500B begins with step 522, which may be a further embodiment of step 404 of flowchart 400 of FIG. 4A. As shown in FIG. 5B, step 522 may be performed subsequent to step 402 of flowchart 400. In step 522, a determination of whether or not a volume setting of a media presentation device is at a maximum level is made. For example, device setting component 326 of FIG. 3 determines whether or not a volume setting of a media presentation device (e.g., speaker 308, consumer electronic device 306D, or another media presentation device) is at a maximum level. The maximum level may be a predetermined level set by a manufacturer of the media presentation device or a level set by a user associated with the media presentation device. Device setting component 326 may determine the volume setting is at a maximum level based on a signal received from the media presentation device (or another consumer electronic device on behalf of the media presentation device) that indicates the volume setting is at a maximum level, an analysis of power consumed by the media presentation device, an analysis of a graphic presented on a screen of a sink device (e.g., consumer electronic device 306D) that indicates the volume level of the media presentation device is at the maximum level (e.g., wherein an image or video of the graphic is captured by camera 318 and provided to switching device 302 as image data or a video data signal), and/or any other analysis, signal, and/or indication that device setting component 326 may utilize to determine the volume setting of the media presentation device is at a maximum level. If device setting adjustment component 326 determines the volume setting of the media presentation device is at the maximum level, flowchart 500B continues to step 524. Otherwise, flowchart 500B continues to step 528.

Step 524 may be a subset of step 404 of flowchart 400 of FIG. 4A. In step 524, a determination to increase the gain setting of a microphone is made. For example, device setting adjustment component 326 of FIG. 3 determines to increase the gain setting of the microphone if the volume setting of the media presentation device is at a maximum level. For instance, suppose device setting adjustment component 326 determines the adjustment event corresponds to an instruction (e.g., included in a command signal received from user device 110 of FIG. 1) or a determination (e.g., based on an analysis of an audio data signal received from listening device 304 of FIG. 3) to increase a level of audio output by the media presentation device. Further suppose device setting adjustment component 326 determined in step 522 that the volume setting of the media presentation device is at a maximum level. In this context, device setting adjustment component 326 determines to increase the gain setting of a microphone (e.g., microphone 312 of FIG. 3 (in an embodiment for calibrating microphone 312) or microphone 112B of FIG. 1 (in an embodiment for facilitating a call between a user of user device 110 and a user of system 300)).

Step 526 may be a subset of step 406 of flowchart 400 of FIG. 4A. In step 526, the first command is transmitted to the microphone. For example, device setting adjustment component 326 of FIG. 3 transmits the first command to the microphone (e.g., microphone 312 or microphone 112B of FIG. 1) or a device comprising the microphone (e.g., listening device 304 or user device 110), as described elsewhere herein. The command includes instructions to increase the gain setting of the microphone. In accordance with an embodiment, the instructions specify an increment to increase the gain setting by. After the command is transmitted to the microphone or device, flowchart 500B continues to step 532.

Step 528 may be a subset of step 404 of flowchart 400 of FIG. 4A. In step 528, a determination to increase the volume setting of the media presentation device is made. For example, device setting adjustment component 326 of FIG. 3 determines to increase the volume setting of the media presentation device. In accordance with an embodiment, device setting adjustment component 326 of FIG. 3 determines to increase the volume setting based on audio analyzer 328 detecting an adjustment event (e.g., in a similar manner as described with respect to steps 504 and 506 of flowchart 500A of FIG. 5A).

Step 530 may be a subset of step 406 of flowchart 400 of FIG. 4A. In step 530, the first command is transmitted to the media presentation device. For example, device setting adjustment component 326 of FIG. 3 transmits the first command to the media presentation device, as described elsewhere herein. The command includes instructions to increase the volume setting of the media presentation device. In accordance with an embodiment, the instructions specify an increment to increase the volume setting by. After the volume setting of the media presentation device is increased, flowchart 500B continues to step 532.

Flowchart 500B ends with step 532. In accordance with an embodiment, step 532 includes detecting an event subsequent to the first event. In this context, switching device 302 is configured to repeat one or more of steps 522-532 (as well as any additional analysis and/or determinations described elsewhere herein) to determine to increase the volume setting of a media presentation device and/or to increase the gain setting of a microphone.

Flowchart 500B has been described with respect to increasing the volume setting of a media presentation device and/or the gain setting of a microphone. It is also contemplated herein that device setting adjustment component 326 may operate to decrease the volume setting of the media presentation device and/or the gain setting of the microphone. For instance, suppose audio analyzer 328 detects an adjustment event and device setting adjustment component 326 determines to decrease audio output by a media presentation device based on the detected adjustment event. Further suppose the volume setting of the media presentation device is below a predetermined level (e.g., at a level that, if further decreased, would decrease the volume of audio output by the media presentation device to zero, near zero, or to a level that is difficult for the user of the media presentation device to hear). The predetermined level may be predetermined by a manufacturer of the media presentation device or set by the user of the media presentation device. In this context, device setting adjustment component 326 determines to decrease the gain of the microphone (e.g., instead of decreasing the volume setting of the media presentation device). Furthermore, by decreasing the gain of the microphone in this manner, device setting adjustment component 326 is able to lower the volume of audio captured by the microphone and played back by the media presentation device without impacting other audio played back by the media presentation device (e.g., audio media content signals, audio of a user interface of the media presentation device, audio captured by another microphone (e.g., in a conference call implementation), etc.).

### III. User Interaction and Presence Detection Embodiments

Several example embodiments have been described herein for calibrating a media presentation device or a microphone via event detection. In some embodiments, the detected event may correspond to the detection of (or lack of detection of) user interaction and/or presence. For instance, switching device 302 of FIG. 3 (or a component thereof) may be configured to detect if a user interacts with listening device 304 (or another component of system 300), if the user has not interacted with listening device 304 (or another component of system 300), if a user is present (e.g., proximate to switching device 302 or the media presentation device), and/or if the user is not present.

As discussed above, switching device 302 may determine if a user has interacted with listening device 304 or another component of system 300. In some embodiments, switching device 302 may operate in various ways to further adjust a volume setting of a media presentation device or a gain setting of a microphone in response to not detecting audio representative of user interaction. For instance, FIG. 6 is a flowchart 600 of a process for transmitting a command to further adjust a volume setting or a gain setting, according to an exemplary embodiment. Switching device 302 may operate to perform the steps of flowchart 600 in an embodiment. Not all steps of flowchart 600 need be performed in all embodiments. Other structural and operational embodiments will be apparent to persons skilled in the relevant art(s) based on the following discussion of FIG. 6 with respect to FIGS. 3 and 4A.

Flowchart 600 begins with step 602. In accordance with an embodiment, step 602 is performed subsequent to a command being transmitted to a listening device or a microphone (e.g., as described with respect to step 406 of flowchart 400 of FIG. 4A). In step 602, a determination that audio representative of user interaction has not been detected for a predetermined time is made. For example, event detector 324 (or a component there of (e.g., triggering event detector 334)) determines audio representative of user interaction of a user of the media presentation device has not been detected (e.g., as an audio data signal received from listening device 304) for a predetermined time. In this context, audio representative of user interaction comprises audio captured by microphone 312 that corresponds to a user of the media presentation device having interacted with microphone 312 (e.g., by speaking into microphone 312). In accordance with an embodiment, audio analyzer 328 analyzes audio data signals received from microphone 312 to determine whether a user has interacted with listening device 304. For instance, suppose microphone 312 captured audio representative of background noise and/or an indirect speech of the user (i.e., the user is otherwise speaking but not speaking to or interacting with microphone 312 (e.g., the user is having a conversation in a room system 300 is located in, the user is having a conversation in another room of the building system 300 is located in, the user is beyond an acceptable range with respect to listening device 304, and/or the user is otherwise not engaging with microphone 312)). In this context, audio analyzer 328 determines audio representative of user interaction with microphone 312 has not been detected and flowchart 600 proceeds to step 604.

As described with respect to step 602, event detector 324 determines audio representative of user interaction of a user of the media presentation device has not been detected for a predetermined time (e.g., a number of seconds, a number of minutes, etc.). The predetermined time in accordance with an embodiment is based on a configuration of switching device 302 (e.g., set by a manufacturer of switching device 302 or a user setting of switching device 302). In embodiments, the predetermined time is considered a “timeout” period. In this context, event detector 324 is able to automatically determine whether or not a user has interacted with microphone 312 subsequent to a command having been transmitted to microphone 312, listening device 304, a microphone of a remotely located computing device (e.g., user device 110 of FIG. 1), and/or a media presentation device. In accordance with an embodiment, event detector 324 detects a “timeout event” in response to the predetermined time lapsing without having detected user interaction.

To better illustrate the embodiments described with respect to step 602 a non-limiting running example is described. In this example, a calling user of user device 110 (“Caller A”) interacts with an interface of user device 110 to initiate a call to switching device 302 of FIG. 3. In this context, device setting adjustment component 326 and/or microphone control component 332 transmits a command to enable processing of audio captured by microphone 312. Suppose the user of system 300 (“Recipient B”) does not answer the call for a predetermined time. For instance, the audio played back by the media presentation device that is ringing may be too low for Recipient B to hear (e.g., the media presentation device is muted, the volume setting of the media presentation device is too low, the gain setting of Caller A's microphone is too low, Recipient B is too far away from the media presentation device, etc.). In this example, event detector 324 determines audio representative of Recipient B having interacted with microphone 312 has not been detected for the predetermined time and flowchart 600 proceeds to step 602.

In step 604, a second command is transmitted, the second command to increase the volume setting of the media presentation device or increase the gain setting of the microphone. For example, device setting adjustment component 326 transmits a second command to the media presentation device or microphone. The second command causes the volume setting of the media presentation device to increase or the gain setting of the microphone to increase. Device setting adjustment component 326 may determine to increase the volume setting or the gain setting in various ways, as described elsewhere herein (e.g., as described with respect to any of flowcharts 400 of FIG. 4A, 500A of FIG. 5A, and/or 500B of FIG. 5B, and/or as otherwise described elsewhere herein).

With continued reference to the non-limiting example described with respect to step 602, suppose the call initiated by Caller A is causing audio to be played back by speaker 308 (e.g., a ring tone of a calling application, audio captured by a microphone of Caller A's device, etc.). In this context, subsequent to event detector 324 determining audio representative of Recipient B interacting with listening device 304 has not been detected, device setting adjustment component 326 determines to increase the volume setting of speaker 308. Device setting adjustment component 326 transmits a command to consumer electronic device 306D to cause the volume setting of speaker 308 to increase.

Alternatively, with continued reference to the non-limiting example, suppose the volume setting of speaker 308 is at a maximum volume. In this context, subsequent to event detector 324 determining audio representative of Recipient B interacting with listening device 304 has not been detected, device setting adjustment component 326 determines to increase the gain setting of Caller A's microphone (e.g., microphone 112B of FIG. 1). Device setting adjustment component 326 transmits a command to Caller A's device (e.g., over a network via network interface 322) to cause the gain setting of the microphone to increase.

In accordance with one or more embodiments, switching device 302 may repeat one or more steps of flowchart 600 subsequent to having transmitted the second command. In this context, switching device 302 may continue repeating the steps of flowchart 600 until audio representative of user interaction is detected. Alternatively, switching device 302 continues repeating the steps of flowchart 600 until the volume setting of the media presentation device and/or the gain setting of the microphone is at a maximum level. In accordance with another alternative embodiment, switching device 302 repeats steps of flowchart 600 up to a maximum number of times or until a second predetermined time is reached. In embodiments wherein no user interaction is detected before switching device 302 stops repeating steps of flowchart 600, switching device 302 may transmit a message to user device 110 indicating the user of switching device 302 could not be reached. In accordance with an embodiment, the message causes a call initiated by user device 110 to be canceled.

As discussed above (and elsewhere herein), switching device 302 may be configured to determine whether or not a user is present. For instance, control logic 314 of FIG. 3 may comprise logic configured in various ways to determine presence of a user. For instance, FIG. 7 is a block diagram of a system 700 for determining presence of a user, according to an exemplary embodiment. As shown in FIG. 7, system 700 comprises user presence determiner 702. In accordance with an embodiment, user presence determiner is sub-logic of control logic 314 of FIG. 3. In an alternative embodiment, user presence determiner 702 is a separate component of switching device 302 of FIG. 3.

User presence determiner 702 is configured to determine whether or not a user is present. For example, user presence determiner 702 may be configured to determine whether or not a user is present based on one or more of, an analysis of audio corresponding to the user's speech captured by microphone 312 of listening device 304, an analysis of an image or a video of the user captured by a camera (e.g., camera 318), an analysis of an output of a sensor of listening device 304 (e.g., a pressure sensor, a push button, an accelerometer, a gyroscope, a fingerprint sensor, a camera, etc.), analysis of data obtained from a smart home application associated with the user (e.g., user location data obtained from a smart home application, room occupancy data obtained from a smart home application, etc.), an analysis of an output of a motion detector (e.g., of a security system), and/or an analysis of other data indicative of user presence.

In embodiments, switching device 302 (or components thereof) may perform one or more steps for calibrating a media presentation device and/or a microphone in response to user presence determiner 702 determining a user is present. To better understand the operation of user presence determiner in this way, FIG. 7 is described with respect to FIG. 8A. FIG. 8A is a flowchart 800 of a process for determining presence of a user, according to an exemplary embodiment. Switching device 302 may operate to perform the steps of flowchart 800 in an embodiment. Not all steps of flowchart 800 need be performed in all embodiments. Other structural and operational embodiments will be apparent to persons skilled in the relevant art(s) based on the following discussion of FIG. 8A with respect to FIGS. 3 and 4A.

Flowchart 800 begins with step 802. In step 802, a determination that a user is proximate to the listening device is made. For example, user presence determiner 702 of FIG. 7 determines that a user is proximate to listening device 304 of FIG. 3. In embodiments, user presence determiner 702 analyzes data to determine if a user is present. For instance, user presence determiner 702 may receive and analyze image or video signals captured by camera 318 to determine if a user is present. In accordance with an embodiment, user presence determiner 702 may use techniques such as facial recognition techniques to recognize a particular user (e.g., a user associated with an application, a user associated with a particular account of an application, a user a caller is intending to call, an owner associated with switching device 302 and/or one or more of consumer electronic devices 306A-306D, a resident of a building switching device 302 is located in (e.g., a resident of a house, a resident of a nursing home, a resident of an apartment, etc.), etc.) present in the analyzed image or video. In accordance with an embodiment, user presence determiner 702 uses techniques to determine if any user or other person is present in the analyzed image or video.

In accordance with another embodiment, user presence determiner 702 of FIG. 7 may receive signals from listening device 304 (e.g., via control interface 320) and analyze the received signals to determine if a user is present. For example, listening device 304 may include a sensor (e.g., a pressure sensor, a push button, an accelerometer, a gyroscope, a fingerprint sensor, a camera, etc.) and provide a signal to user presence determiner 702 via control interface 320 indicating the output of the sensor. In this context, user presence determiner 702 analyzes the output of the sensor of listening device 304 to determine if a user is present. In accordance with an alternative embodiment, listening device 304 analyzes the output of the sensor to determine if a user is present. In this context, listening device 304 transmits a signal indicating if the user is present to user presence determiner 702, which analyzes the received signal to determine if the user is present.

In accordance with another embodiment, user presence determiner 702 of FIG. 7 may analyze data obtained from an application associated with a user, a consumer electronic device (e.g., consumer electronic device(s) 306A-306D), and/or the building switching device 302 is located in to determine if a user is present. For example, user presence determiner 702 may obtain data from a smart home application associated with a user (e.g., via network interface 322). Examples of data user presence determiner 702 may obtain from a smart home application (and/or another suitable application) include, but are not limited to, user location data, room occupancy data, user habit or routine data, and/or any other data that may be analyzed to indicate if a user is present.

In accordance with an embodiment, user presence determiner 702 of FIG. 7 may analyze an output of a motion detector to determine if a user is present. Example motion detectors include, but are not limited to, security system motion sensors, smart home motion sensors, motion sensors incorporated in a mobile device (e.g., a phone or tablet), and/or any other sensor for detecting motion (e.g., of a user). In accordance with an embodiment, the motion sensor is coupled to a port of switching device 302 (e.g., as a built-in motion sensor of a consumer electronic device 306A-306D or as a standalone motion sensor) and user presence determiner 702 obtains the output of the motion sensor via switch circuit 316. In accordance with another embodiment, the motion sensor is incorporated in camera 318. In accordance with another embodiment, the motion sensor is incorporated in listening device 304. In accordance with another embodiment, user presence determiner 702 obtains the output of the motion sensor via network interface 322 (e.g., from the motion sensor, from an application associated with the motion sensor, from a security system associated with the motion sensor, and/or the like).

As shown in FIG. 8A, subsequent to determining a user is proximate to listening device 304, flowchart 800 continues to step 402 of flowchart 400, as described with respect to FIG. 4A. For example, in accordance with an embodiment, audio analyzer 328 analyzes audio data signals subsequent to user presence determiner 702 determining a user is proximate to listening device 304. By receiving and analyzing audio data signals subsequent to determining the presence of the user, embodiments described herein are able to determine whether or not to adjust a volume setting of a media presentation device (e.g., speakers 308), a gain setting of microphone 312, and/or a gain setting of a microphone of a remotely located computing device (e.g., microphone 112B of FIG. 1) based on the location of the user. In other words, if the user is proximate to listening device 304, the audio captured by microphone 312 is similar to the audio heard by the user. Therefore, audio analyzer 328 analyzes audio similar to the that heard by the user and device setting adjustment component 326 determines whether or not to adjust the volume setting of the media presentation device, the gain setting of microphone 312, and/or the gain setting of microphone 112B based on the analysis of audio similar to that heard by the user.

As discussed above, switching device 302 may perform steps for calibrating a microphone and/or media presentation device in response to determining a user is proximate to listening device 304. In some embodiments, further steps may be performed (e.g., prior to one or more steps of flowchart 400) in response to determining a user is proximate to listening device 304. For example, FIG. 8B is a flowchart 810 of a process for turning on a microphone of a remote control device based on determining a user presence, according to an exemplary embodiment. Switching device 302 may operate to perform the steps of flowchart 810 in an embodiment. Not all steps of flowchart 810 need be performed in all embodiments. Other structural and operational embodiments will be apparent to persons skilled in the relevant art(s) based on the following discussion of FIG. 8B with respect to FIGS. 3, 4A, and 8A.

Flowchart 810 begins with step 812. As shown in FIG. 8B, step 812 may be performed subsequent to step 802 of flowchart 800, as described above with respect to FIG. 8A. In step 812, a second command is transmitted to the remote control device responsive to determining the user is proximate to the remote control device. The second command comprises instructions to turn on the microphone. For example, microphone control component 332 of FIG. 3 transmits a command to listening device 304 in response to user presence determiner 702 having determined that a user is proximate to listening device 304. In this context, the command includes instructions to turn on microphone 312.

As shown in FIG. 8B, subsequent to transmitting the command to listening device 304 to turn on microphone 312, flowchart 810 may continue to step 402 of flowchart 400. For example, in accordance with an embodiment, audio analyzer 328 receives and analyzes audio data signals subsequent to microphone control component 332 having transmitted a command to turn on microphone 312 in response to user presence determiner 702 determining a user is proximate to listening device 304. By turning on microphone 312 subsequent to determining the presence of the user, power consumed by listening device 304 is reduced, thereby increasing battery life of listening device 304.

### IV. Embodiments for Detecting Triggering Events

Switching device 302 of FIG. 3 may perform steps for calibrating a media presentation device and/or a microphone in response to detecting a triggering event. For example, FIG. 9 is a flowchart 900 of a process for detecting a triggering event, according to an exemplary embodiment. Switching device 302 may operate to perform the steps of flowchart 900 in an embodiment. Flowchart 900 need not be performed in all embodiments. Other structural and operational embodiments will be apparent to persons skilled in the relevant art(s) based on the following discussion of FIG. 9 with respect to FIGS. 3 and 4A.

Flowchart 900 begins with step 902. In step 902, a triggering event is detected. For example, triggering event detector 334 of FIG. 3 detects a triggering event. As described elsewhere herein, triggering event detector 334 may detect a triggering event based at least on an analysis of data (e.g., signals received by control logic 314). For instance, triggering event detector 334 in accordance with an embodiment detects a triggering event based at least on an analysis of media content signals. For example, in accordance with an embodiment, triggering event detector 334 detects the triggering event based at least on an analysis of a media content signal provided by a source device (e.g., one or more of consumer electronic devices 306A-306C) and/or an analysis of a media content signal provided to a media presentation device (e.g., consumer electronic device 306D and/or speakers 308). Triggering event detector 334 may access media content signals via switch circuit 316 to monitor the media content signals (e.g., provided to consumer electronic device 306D). In accordance with an embodiment, triggering event detector 334 may detect a triggering event by identifying content in the media content signal that is indicative of the occurrence of an incoming/outgoing audio or video call, an application with audio input/output features enabled, an application in a state to accept user input, an application with audio input/output features, and/or the like.

In accordance with another embodiment, triggering event detector 334 of FIG. 3 detects the triggering event based at least on an analysis of an audio data signal (e.g., received from listening device 304, an internal microphone of switching device 302, an external microphone coupled to switching device 302, and/or via a network interface from a microphone of a remotely located computing device). For example, triggering event detector 334 may be configured to perform a cross correlation of the audio data signal captured by microphone 312 and/or the audio data signal captured by microphone 112B of FIG. 1 and an audio signature representative of a triggering event. Audio signatures may be stored as audio signature files within a storage of switching device 302 (not shown in FIG. 3), an external storage device coupled to switching device 302 (e.g., an external hard drive, a storage of a consumer electronic device, etc.), and/or a network-accessible storage (e.g., cloud storage). Example audio signatures include, but are not limited to, an audio signature representative of an incoming video or audio call tone, an audio signature of an application launch or loading screen, a chime (e.g., indicating audio features are enabled, indicating an application is in a state to accept user input, etc.), and/or any other auditory sound that triggering event detector 334 may analyze to detect an event. In this context, triggering event detector 334 compares the audio data signal captured by microphone 312 to one or more such audio signatures (e.g., via cross correlation). In accordance with an embodiment, audio analyzer 328 is configured to perform such analysis on behalf of triggering event detector 334. In this context, audio analyzer 328 provides the analysis of the received audio data signal to triggering event detector 334, which detects a triggering event based at least on the results of the analysis.

In accordance with another embodiment, triggering event detector 334 of FIG. 3 detects the triggering event based at least on an analysis of an image or video captured by camera 318. For example, camera 318 in accordance with an embodiment captures an image or a video of a media presentation device (e.g., consumer electronic device 306D) and provides a corresponding image or video signal to triggering event detector 334 (e.g., via network interface 322, as shown in FIG. 3). In this context, triggering event detector 334 analyzes the corresponding image or video signal in order to detect a triggering event. For example, triggering event detector 334 may use image recognition to recognize a particular user interface icon, media image, or other visual content displayed on a media presentation device. It is also contemplated herein that camera 318 may capture image or videos of other consumer electronic devices, users, and/or other subjects that may be used to detect the first event.

In accordance with another embodiment, triggering event detector 334 of FIG. 3 detects the triggering event based at least on user presence determiner 702 of FIG. 7 having detected the presence of a user. For example, user presence determiner 702 may determine a user is in the same room (or building) as switching device 302 and/or the media presentation device (e.g., consumer electronic device 306D and/or speakers 308), determine a user is proximate to listening device 304, and/or otherwise determine a user is present. User presence determiner 702 may detect the presence of the user in any manner described elsewhere herein, or as would be understood by a person ordinarily skilled in the relevant art(s) having benefit of this disclosure.

As shown in FIG. 9, step 902 may precede step 402 of flowchart 400 of FIG. 4A. For instance, detecting a triggering event may prompt switching device 302 of FIG. 3 to receive and/or analyze a command signal and/or an audio data signal (e.g., subsequent to the detection of the triggering event) to further detect an adjustment event. Alternatively, step 902 is a subset of step 402 of flowchart 400. For instance, step 902 in one alternative embodiment is subsequent to step 412 and prior to step 414 of flowchart 410 of FIG. 4B. In another alternative embodiment, step 902 is subsequent to step 422 and prior to step 424 of flowchart 420 of FIG. 4C. In accordance with an embodiment, subsequent to triggering event detector 334 detecting the triggering event, switching device 302 transmits a command to listening device 304 that includes instructions to enable processing of audio captured by microphone 312.

### V. Further Example Embodiments of Media Systems

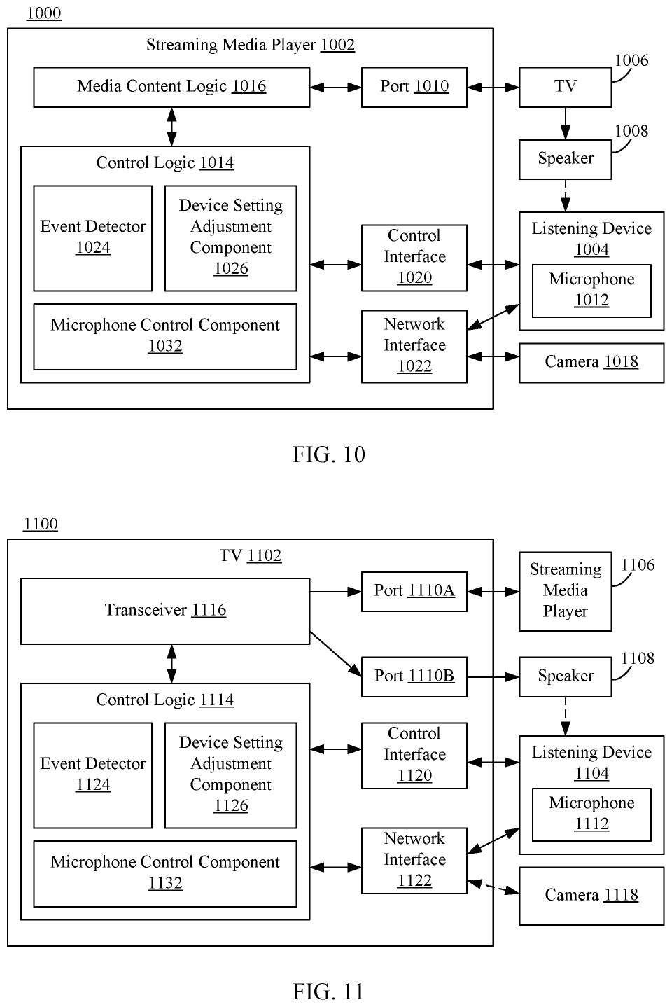

Exemplary embodiments have been described above with respect to a switching device (e.g., switching device 302 of FIG. 3) that is configured to calibrate a media presentation device and/or microphone via event detection. However, one or more embodiments described herein may be incorporated in any other device, or as a stand-alone device, configured to calibrate a media presentation device and/or microphone via event detection. For instance, a source device in accordance with an embodiment may be configured to calibrate a media presentation device and/or microphone via event detection. For example, FIG. 10 is a block diagram of a media system (“system 1000” hereinafter) configured to calibrate a media presentation device or microphone via event detection, according to another exemplary embodiment. System 1000 is an example of system 200, as described above with reference to FIG. 2. System 1000 includes a streaming media player 1002, a listening device 1004, a consumer electronic device 1006, one or more speakers 1008 (“speakers 1008” hereinafter), and a camera 1018. Listening device 1004 is an example of listening device 304, as described above with reference to FIG. 3, and includes a microphone 1012, which is an example of microphone 312. Consumer electronic device 1006, speakers 1008, and camera 1018 are examples of consumer electronic device 306D, speakers 308, and camera 318 of FIG. 3, respectively. In accordance with an embodiment, system 1000 may include a switching device (such as switching device 302 of FIG. 3) coupled between streaming media player 1002 and consumer electronic device 1006, not shown in FIG. 3. In accordance with another embodiment, such switching device is incorporated in streaming media player 1002.

As shown in FIG. 10, streaming media player 1002 includes control logic 1014, media content logic 1016, port 1010, control interface 1020, and network interface 1022. Control logic 1014, control interface 1020, and network interface 1022 operate in similar respective manners as control logic 314, control interface 320, and network interface 322, as described above with respect to FIG. 3. While a single port 1010 is shown in FIG. 10, embodiments of streaming media player 1002 may include any number of ports, as described herein.

Media content logic 1016 is configured to provide media content signals to consumer electronic device 1006 via port 1010. For example, a user (via listening device 1004) may interact, view, search, and/or select content for media content logic 1016 to provide to consumer electronic device 1006. In embodiments, media content logic 1016 may access media content over a network via network interface 1022 to provide the media content signals.

As described above, control logic 1014 operates in a similar manner as control logic
314 of FIG. 3. Furthermore, control logic 1014 controls media content logic 1016 (e.g., based on input received via remote control device 1004, via network interface 1022, and/or according to actions determined by control logic 1014 or a component thereof). As shown in FIG. 10, control logic 1014 includes an event detector 1024, a device setting adjustment component 1026, and a microphone control component 1032, which may each operate in similar respective manners as event detector 324, device setting adjustment component 326, and microphone control component 332, as described above with respect to FIG. 3.

As described above, one or more embodiments may be incorporated in a device other than a switching device configured to calibrate a media presentation device or microphone via event detection. For instance, a media presentation device in accordance with an embodiment may be configured to calibrate a speaker or microphone via event detection. For example, FIG. 11 is a block diagram of a media system (“system 1100” hereinafter) configured to calibrate a speaker or a microphone via event detection, according to another exemplary embodiment. System 1100 is an example of system 200 as described above with reference to FIG. 2. System 1100 includes a TV 1102, a listening device 1104, a consumer electronic device 1106, one or more speakers 1108 (“speakers 1108” hereinafter), and a camera 1118. Listening device 1104 is an example of listening device 304, as described above with reference to FIG. 3, and includes a microphone 1112, which is an example of microphone 312. Consumer electronic device 1106, speakers 1108, and camera 1118 are examples of consumer electronic device 306D, speakers 308, and camera 318 of FIG. 3, respectively. In accordance with an embodiment, system 1100 may include a switching device (such as switching device 302 of FIG. 3) coupled between TV 1102 and consumer electronic device 1106, not shown in FIG. 3. In accordance with another embodiment, such switching device is incorporated in TV 1102.

As shown in FIG. 11, TV 1102 includes ports 1110A and 1110B, a control logic 1114, transceiver 1116, a control interface 1120, and a network interface 1122. Control logic 1114, control interface 1120, and network interface 1122 operate in similar respective manners as control logic 314, control interface 320, and network interface 322, as described above with respect to FIG. 3. While two ports 1110A and 1110B are shown in FIG. 11, embodiments of TV 1102 may include a single port or more than two ports, as described herein.

Transceiver 1116 is configured to receive media content signals from consumer electronic device 1106 via port 1110A for display on a screen of TV 1102 (not shown in FIG. 11). Furthermore, transceiver 1116 is configured to provide audio data signals of received media content signals to speakers 1108 via port 1110B. In embodiments, transceiver 1116 may also be configured to send commands to consumer electronic device 1106 from control logic 1114 via port 1110A.

As described above, control logic 1114 operates in a similar manner as control logic 314 of FIG. 3. Furthermore, control logic 1114 may access signals (e.g., media content signals) received by or provided by transceiver 1116, transmit commands to consumer electronic device 1106 and/or speakers 1108 via transceiver 1116, and/or the like. As shown in FIG. 11, control logic 1114 includes an event detector 1124, a device setting adjustment component 1126, and a microphone control component 1132, which may each operate in similar respective manners as event detector 324, device setting adjustment component 326, and microphone control component 332, as described above with respect to FIG. 3.

### VI. Further Example Embodiments and Advantages

Various embodiments for media presentation device and/or microphone calibration via event detection have been described herein with respect to transmitting commands to a media presentation device (e.g., to adjust a volume setting thereof), to a listening device (e.g., to adjust a gain setting of a microphone of the listening device), and/or to a remotely located computing device (e.g., to adjust a gain setting of a microphone of the computing device). However, it is also contemplated that embodiments may transmit commands to other devices. For instance, in accordance with an example embodiment, a device setting adjustment component may transmit a command to a source device, the command including instructions to adjust a volume setting of the source device. In accordance with another example embodiment, a device setting adjustment component may transmit a command to a sink device other than a media presentation device, the command including instructions to adjust a volume setting of the sink device and/or one or more speakers coupled to the sink device.

Furthermore, a device setting adjustment component may transmit a command to a listening device other than a remote control device or a smart home device. For instance, the device setting adjustment component may transmit a command to another type of listening device (e.g., a webcam, a camera, a consumer electronic device, and/or the like) with an internal microphone or an external microphone coupled thereto, the command including instructions to adjust a gain setting of the internal or external microphone. For example, as described elsewhere herein, a device setting adjustment component may transmit a command to a computing device (e.g., over a network) with an internal microphone or an external microphone coupled thereto, the command including instructions to adjust a gain setting of the internal or external microphone.

Furthermore, several running examples have been described with respect to adjusting a gain setting of a microphone. It is also contemplated herein that embodiments may adjust a sensitivity setting of a microphone. For instance, the sensitivity setting of a microphone may be reduced to reduce the amount of background noise in captured audio. Alternatively, the sensitivity setting of a microphone may be increased to improve the capture of a speaking user's voice (or other audio played back and captured by the microphone (e.g., audio content played back by a speaker)).

A device, as defined herein, is a machine or manufacture as defined by 35 U.S.C. § 101. Devices may be digital, analog or a combination thereof. Devices may include integrated circuits (ICs), one or more processors (e.g., central processing units (CPUs), microprocessors, digital signal processors (DSPs), etc.) and/or may be implemented with any semiconductor technology, including one or more of a Bipolar Junction Transistor (BJT), a heterojunction bipolar transistor (HBT), a metal oxide field effect transistor (MOSFET) device, a metal semiconductor field effect transistor (MESFET) or other transconductor or transistor technology device. Such devices may use the same or alternative configurations other than the configuration illustrated in embodiments presented herein.

Techniques and embodiments, including methods, described herein may be implemented in hardware (digital and/or analog) or a combination of hardware and software and/or firmware. Techniques described herein may be implemented in one or more components. Embodiments may comprise computer program products comprising logic (e.g., in the form of program code or instructions as well as firmware) stored on any computer useable storage medium, which may be integrated in or separate from other components. Such program code, when executed in one or more processors, causes a device to operate as described herein. Devices in which embodiments may be implemented may include storage, such as storage drives, memory devices, and further types of computer-readable media. Examples of such computer-readable storage media include, but are not limited to, a hard disk, a removable magnetic disk, a removable optical disk, flash memory cards, digital video disks, random access memories (RAMs), read only memories (ROM), and the like. In greater detail, examples of such computer-readable storage media include, but are not limited to, a hard disk associated with a hard disk drive, a removable magnetic disk, a removable optical disk (e.g., CDROMs, DVDs, etc.), zip disks, tapes, magnetic storage devices, MEMS (micro-electromechanical systems) storage, nanotechnology-based storage devices, as well as other media such as flash memory cards, digital video discs, RAM devices, ROM devices, and the like. Such computer-readable storage media may, for example, store computer program logic, e.g., program modules, comprising computer executable instructions that, when executed, provide and/or maintain one or more aspects of functionality described herein with reference to the figures, as well as any and all components, steps, and functions therein and/or further embodiments described herein.

Computer readable storage media are distinguished from and non-overlapping with communication media (do not include communication media or modulated data signals). Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wired media as well as wireless media such as acoustic, RF, infrared and other wireless media. Example embodiments are also directed to such communication media.

The media presentation device or microphone calibration embodiments and/or any further systems, sub-systems, and/or components disclosed herein may be implemented in hardware (e.g., hardware logic/electrical circuitry), or any combination of hardware with software (computer program code configured to be executed in one or more processors or processing devices) and/or firmware.

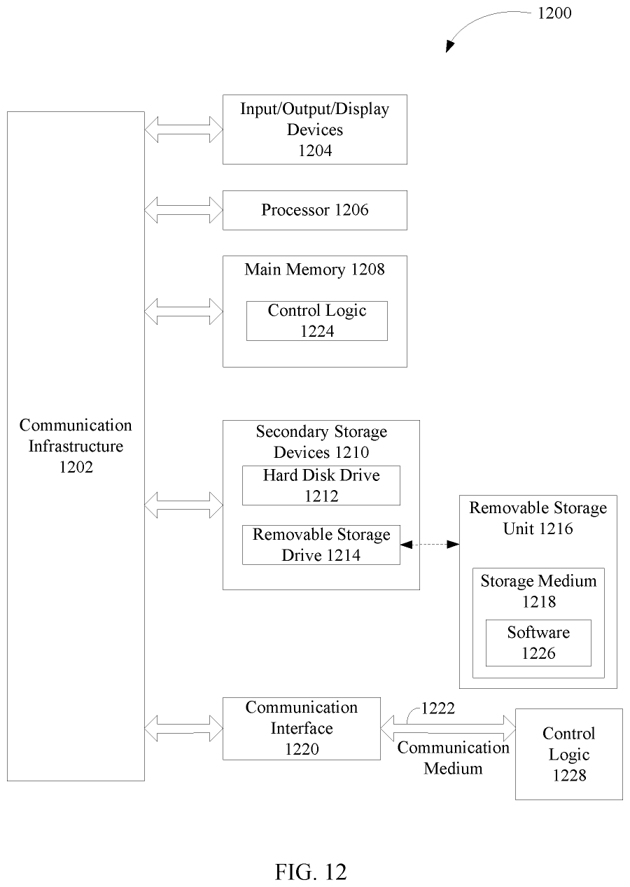

The embodiments described herein, including systems, methods/processes, and/or apparatuses, may be implemented using well known processing devices, servers, electronic devices (e.g., consumer electronic devices) and/or, computers, such as a computer 1200 shown in FIG. 12. It should be noted that computer 1200 may represent communication devices, processing devices, servers, and/or traditional computers in one or more embodiments. For example, switching device 102, listening device 104, consumer electronic device 106, user device 110, microphone 112A, and/or microphone 112B as described above in reference to FIG. 1, switching device 202, remote control device 204A, smart home device 204B, one or more of consumer electronic device(s) 206A-206D, speakers 208, and/or microphone 212 as described above in reference to FIG. 2, switching device 302 (and/or the components thereof), listening device 304 (and/or the components thereof), one or more of consumer electronic device(s) 306-306D, speakers 308, and/or camera 318 as described above in reference to FIG. 3, user presence determiner 702 as described above in reference to FIG. 7, streaming media player 1002 (and/or the components thereof), listening device 1004 (and/or the components thereof), consumer electronic device 1006, speakers 1008, and/or camera 1018 as described above in reference to FIG. 10, TV 1102 (and/or the components thereof), listening device 1104 (and/or the components thereof), consumer electronic device 1106, speakers 1108, and/or camera 1118 as described above in reference to FIG. 11, and/or flowcharts 400, 410, 420, 500A, 500B, 600, 800, 810, and/or 900 may be implemented using one or more computers 1200.

Computer 1200 can be any commercially available and well-known communication device, processing device, and/or computer capable of performing the functions described herein, such as devices/computers available from International Business Machines®, Apple®, Sun®, HP®, Dell®, Cray®, Samsung®, Nokia®, etc. Computer 1200 may be any type of computer, including a desktop computer, a server, etc.

Computer 1200 includes one or more processors (also called central processing units, or CPUs), such as a processor 1206. Processor 1206 is connected to a communication infrastructure 1202, such as a communication bus. In some embodiments, processor 1206 can simultaneously operate multiple computing threads.

Computer 1200 also includes a primary or main memory 1208, such as random access memory (RAM). Main memory 1208 has stored therein control logic 1224 (computer software), and data.

Computer 1200 also includes one or more secondary storage devices 1210. Secondary storage devices 1210 include, for example, a hard disk drive 1212 and/or a removable storage device or drive 1214, as well as other types of storage devices, such as memory cards and memory sticks. For instance, computer 1200 may include an industry standard interface, such a universal serial bus (USB) interface for interfacing with devices such as a memory stick. Removable storage drive 1214 represents a floppy disk drive, a magnetic tape drive, a compact disk drive, an optical storage device, tape backup, etc.

Removable storage drive 1214 interacts with a removable storage unit 1216. Removable storage unit 1216 includes a computer useable or readable storage medium 1218 having stored therein computer software 1226 (control logic) and/or data. Removable storage unit 1216 represents a floppy disk, magnetic tape, compact disk, DVD, optical storage disk, or any other computer data storage device. Removable storage drive 1214 reads from and/or writes to removable storage unit 1216 in a well-known manner.

Computer 1200 also includes input/output/display devices 1204, such as touchscreens, LED and LCD displays, monitors, keyboards, pointing devices, etc.

Computer 1200 further includes a communication or network interface 1220. Communication interface 1220 enables computer 1200 to communicate with remote devices. For example, communication interface 1220 allows computer 1200 to communicate over communication networks or mediums 1222 (representing a form of a computer useable or readable medium), such as LANs, WANs, the Internet, etc. Network interface 1220 may interface with remote sites or networks via wired or wireless connections.

Control logic 1228 may be transmitted to and from computer 1200 via the communication medium 1222.

Any apparatus or manufacture comprising a computer useable or readable medium having control logic (software) stored therein is referred to herein as a computer program product or program storage device. This includes, but is not limited to, computer 1200, main memory 1208, secondary storage devices 1210, and removable storage unit 1216. Such computer program products, having control logic stored therein that, when executed by one or more data processing devices, cause such data processing devices to operate as described herein, represent embodiments of the invention.

Any apparatus or manufacture comprising a computer useable or readable medium having control logic (software) stored therein is referred to herein as a computer program product or program storage device. This includes, but is not limited to, a computer, computer main memory, secondary storage devices, and removable storage units. Such computer program products, having control logic stored therein that, when executed by one or more data processing devices, cause such data processing devices to operate as described herein, represent embodiments of the inventive techniques described herein.

### VII. Conclusion

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described exemplary embodiments, but should be defined only in accordance with the following claims and their equivalents.

What is claimed is:

1. A method performed by a first computing device associated with a first user, comprising:
detecting an adjustment event based on an analysis of at least one of:
an audio data signal received from a listening device, or
a command signal received from a second computing device via a network interface, the command signal comprising instructions to adjust a volume setting of a media presentation device, the second computing device associated with a second user and remotely located from the first computing device;
determining to adjust at least one of the volume setting of the media presentation device or a gain setting of a microphone based at least on the detected adjustment event; and
responsive to said determining, transmitting a first command to at least one of the media presentation device or the microphone.

2. The method of claim 1, wherein said detecting the adjustment event is based on the analysis of the audio data signal;
the listening device comprises the microphone; and
the audio data signal is representative of audio played back by the media presentation device and captured by the microphone.

3. The method of claim 1, wherein the second computing device comprises the microphone.

4. The method of claim 3, wherein:
said determining to adjust at least one of the volume setting or the gain setting comprises:
determining the volume setting of the media presentation device is at a maximum level, and
determining to increase the gain of the microphone; and
said transmitting the first command to the microphone comprises transmitting the first command to the second computing device to cause the second computing device to increase the gain of the microphone.

5. The method of claim 1, wherein said detecting the adjustment event comprises determining a volume of the audio data signal.

6. The method of claim 5, wherein said determining to adjust at least one of the volume setting or the gain setting comprises:
determining to increase the volume setting if the volume of the audio data signal is below a first threshold; and
determining to decrease the volume setting if the volume of the audio data signal is above a second threshold greater than the first threshold.

7. The method of claim 1, further comprising, subsequent to said transmitting the first command:
determining audio representative of user interaction has not been detected for a predetermined time; and
transmitting a second command to increase the volume setting of the media presentation device or increase the gain setting of the microphone device.

8. A system associated with a first user, comprising:
an event detector that:
detects an adjustment event based on an analysis of at least one of:
an audio data signal received from a listening device, or
a command signal received from a computing device via a network interface of the system, the command signal comprising instructions to adjust a volume setting of a media presentation device, the computing device associated with a second user and remotely located from the system;
a device setting adjustment component that:
determines to adjust a gain setting of a microphone based at least on the detected adjustment event; and
responsive to the determination to adjust the gain setting, transmits a first command to the microphone, the first command comprising instructions to adjust the gain setting.

9. The system of claim 8, wherein the event detector detects the adjustment event based on the analysis of the audio data signal;
the listening device comprises the microphone; and
the audio data signal is representative of audio played back by the media presentation device and captured by the microphone.

10. The system of claim 8, wherein the computing device comprises the microphone.

11. The system of claim 10, wherein:
to determine to adjust the gain setting, the device setting adjustment component:
determines the volume setting of the media presentation device is at a maximum level, and
determines to increase the gain of the microphone; and
to transmit the first command to the microphone, the device setting adjustment component transmits the first command to the computing device to cause the computing device to increase the gain of the microphone.

12. The system of claim 8, wherein to detect the adjustment event, the event detector:
determines a volume of the audio data signal.

13. The system of claim 12, wherein to determine to adjust the gain setting the device setting adjustment component further:
determines to increase the gain setting if the volume of the audio data signal is below a first threshold; and
determines to decrease the gain setting if the volume of the audio data signal is above a second threshold greater than the first threshold.

14. The system of claim 8, wherein:
subsequent to the transmission of the first command to the microphone, the event detector determines audio representative of user interaction has not been detected for a predetermined time; and
the device setting adjustment component further transmits a second command comprising instructions to increase the gain setting of the microphone device.

15. A system associated with a first user, comprising:
an event detector that:
detects a first adjustment event based on an analysis of at least one of:
an audio data signal received from a listening device, or
a command signal received from a computing device via a network interface of the system, the command signal comprising instructions to adjust a volume setting of a media presentation device, the computing device associated with a second user and remotely located from the system;
a device setting adjustment component that:
determines to adjust a volume setting of the media presentation device based at least on the first adjustment event; and
responsive to the determination to adjust the volume setting, transmits a first command to the media presentation device, the first command comprising instructions to adjust the volume setting.

16. The system of claim 15, wherein the event detector detects the adjustment event based on the analysis of the audio data signal;
the listening device comprises the microphone; and
the audio data signal is representative of audio played back by the media presentation device and captured by the microphone.

17. The system of claim 15, wherein:
the event detector detects a second adjustment event based on an analysis of audio captured by the listening device subsequent to the transmission of the first command; and
the device setting adjustment component further:
determines the volume setting of the media presentation device is at a maximum level,
determines to increase a gain setting of a microphone of the computing device, and
transmits a second command to the computing device to cause the computing device to increase the gain setting of the microphone.

18. The system of claim 15, wherein to detect the adjustment event, the event detector determines a volume of the audio data signal.

19. The system of claim 18, wherein to determine to adjust the volume setting, the device adjustment component further:
determines to increase the volume setting if the volume of the received audio signal is below a first threshold; and
determines to decrease the volume setting if the volume of the received audio signal is above a second threshold greater than the first threshold.

20. The system of claim 15, wherein:
subsequent to the transmission of the first command to the microphone, the event detector determines audio representative of user interaction has not been detected for a predetermined time; and
the device setting adjustment component further transmits a second command comprising instructions to increase the volume setting of the media presentation device.
